(19) United States
(12) Patent Application Publication
(10) Pub. No.: US 2016/0154268 A1
(43) Pub. Date: Jun. 2, 2016

(54) DISPLAY PANEL AND DISPLAY MODULE

(71) Applicant: Semiconductor Energy Laboratory Co., Ltd., Atsugi-shi (JP)

(72) Inventors: Shunpei YAMAZAKI, Tokyo (JP); Yasuhiro JINBO, Isehara (JP); Kenichi OKAZAKI, Tochigi (JP)

(21) Appl. No.: 14/948,559

(22) Filed: Nov. 23, 2015

(30) Foreign Application Priority Data
Dec. 1, 2014 (JP) 2014-243348

(51) Int. Cl. G02F 1/1345; H01L 27/32; H01L 51/56; G02F 1/1333; H01L 51/52

(52) U.S. Cl. CPC G02F 1/13452; G02F 1/133345; H01L 51/5246; H01L 51/56; H01L 27/3276; H01L 2251/5338; H01L 2227/323

(57) ABSTRACT

A novel display panel excellent in convenience or reliability, or a novel display panel with excellent mountability on a housing is provided. The display panel includes a terminal, a first base that supports the terminal, the second base that has a region overlapping with the first base, a bonding layer that bonds the first base to the second base, a display element that is between the first base and the second base and is electrically connected to the terminal, and an insulating layer that is in contact with the first base, the second base, and the bonding layer. The insulating layer includes an opening in a region overlapping with the display element.

### BACKGROUND OF THE INVENTION

1. Field of the Invention

One embodiment of the present invention relates to a display panel. Another embodiment of the present invention relates to a display module.

Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter. Specifically, examples of the technical field of one embodiment of the present invention disclosed in this specification include a semiconductor device, a display device, a light-emitting device, a power storage device, a memory device, a method for driving any of them, and a method for manufacturing any of them.

2. Description of the Related Art

Functions of some functional elements are impaired because of impurity diffusion. In order to maintain the functions of such functional elements, the following invention is known (Patent Document 1): a functional element is sealed in a space surrounded by a substrate provided with the functional element, a sealing substrate, and a sealant for bonding the substrate and the sealing substrate.

The following invention is also known (Patent Document 2): in a manufacturing process of a light-emitting device, a light-emitting panel is manufactured which is at least partly curved by processing the shape to be molded after the manufacture of an electrode layer and/or an element layer, and a protective film covering a surface of the light-emitting panel which is at least partly curved is formed, so that a light-emitting device including the light-emitting panel has a more useful function and higher reliability.

### REFERENCE

### Patent Document

[Patent Document 1] United States Published Patent Application No. 2007/0170854
[Patent Document 2] Japanese Published Patent Application No. 2011-003537

### SUMMARY OF THE INVENTION

An object of one embodiment of the present invention is to provide a novel display panel with improved convenience or reliability, a novel display panel of which mountability on a housing is excellent, a novel display panel with lower power consumption, a novel display module, or a novel semiconductor device.

Note that the descriptions of these objects do not preclude the existence of other objects. In one embodiment of the present invention, there is no need to achieve all the objects. Other objects will be apparent from and can be derived from the description of the specification, the drawings, the claims, and the like.

One embodiment of the present invention is a display panel including a terminal, a first base that supports the terminal, a second base that includes a region overlapping with the first base, a bonding layer that bonds the first base to the second base, a display element that is between the first base and the second base and is electrically connected to the terminal, and an insulating layer that is in contact with the first base, the second base, and the bonding layer. The insulating layer includes an opening in a region overlapping with the display element.

Another embodiment of the present invention is the above display panel further including a resin layer, in which the insulating layer includes a region sandwiched between the bonding layer and the resin layer.

Another embodiment of the present invention is the above display panel in which the display element includes a light-emitting organic compound.

Another embodiment of the present invention is the above display panel in which the first and second bases have flexibility.

Another embodiment of the present invention is the above display panel in which the display element includes a liquid crystal.

Another embodiment of the present invention is a display module including the above display panel and a flexible printed circuit that is electrically connected to the terminal.

Another embodiment of the present invention is a method for manufacturing the above display panel, including a first step of preparing a processed member including the terminal, the first base that supports the terminal, the second base that includes the region overlapping with the first base, the bonding layer that bonds the first base to the second base, and the display element that is between the first base and the second base and is electrically connected to the terminal and forming a mask in a region overlapping with the display element, a second step of forming the insulating layer that is in contact with the first base, the second base, and the bonding layer by an atomic layer deposition method, and a third step of removing part of the insulating layer together with the mask.

Note that in this specification, an “EL layer” refers to a layer provided between a pair of electrodes in a light-emitting element. Thus, a light-emitting layer containing an organic compound as a light-emitting substance which is interposed between electrodes is an embodiment of an EL layer.

In this specification, in the case where a substance A is dispersed in matrix formed using a substance B, the substance B forming the matrix is referred to as a host material, and the substance A dispersed in the matrix is referred to as a guest material. Note that the substance A and the substance B may each be a single substance or a mixture of two or more kinds of substances.

Note that the term light-emitting device in this specification means a display device or a light source (including a lighting device). In addition, the light-emitting device might include any of the following modules in its category: a module in which a connector such as a flexible printed circuit (FPC) or a tape carrier package (TCP) is attached to a light-emitting device; a module having a TCP provided with a printed wiring board at the end thereof; and a module having an integrated circuit (IC) directly mounted on a substrate over which a light-emitting element is formed by means of a chip on glass (COG) method.

Note that the terms “film” and “layer” can be interchanged with each other depending on the case or circumstances. For example, the term “conductive layer” can be changed into the term “conductive film” in some cases. Also, the term “insulating film” can be changed into the term “insulating layer” in some cases.

In this specification, one of a first electrode and a second electrode of a transistor refers to a source electrode and the other refers to a drain electrode.

According to one embodiment of the present invention, a novel display panel with improved convenience or reliability, a novel display panel of which mountability on a housing is excellent, a novel display panel with lower power consumption, a novel display module, or a novel semiconductor device can be provided.

Note that the description of these effects does not preclude the existence of other effects. One embodiment of the present invention does not necessarily achieve all the effects listed above. Other effects will be apparent from and can be derived from the description of the specification, the drawings, the claims, and the like.

### BRIEF DESCRIPTION OF THE DRAWINGS

In the accompanying drawings:

FIGS. 1A to 1C illustrate the structures of a display panel of an embodiment;

FIGS. 2A to 2C illustrate the structures of a display panel of an embodiment;

FIGS. 3A to 3C illustrate the structures of a display panel of an embodiment;

FIGS. 4A to 4C illustrate the structures of a display panel of an embodiment;

FIGS. 5A to 5C illustrate the structures of a display panel of an embodiment;

FIGS. 6A to 6C illustrate the structures of a display module of an embodiment;

FIGS. 7A to 7C illustrate the structures of a display module of an embodiment;

FIG. 8 is a flow chart illustrating a method for manufacturing a display panel of an embodiment;

FIGS. 9A to 9C illustrate a method for manufacturing a display panel of an embodiment;

FIGS. 10A and 10B illustrate a method for manufacturing a display panel of an embodiment;

FIGS. 11A and 11B illustrate a method for manufacturing a display panel of an embodiment;

FIG. 12 illustrates the structure of a film formation apparatus of an embodiment;

FIGS. 13A to 13C illustrate a method for manufacturing a display panel of an embodiment;

FIGS. 14A and 14B illustrate a structural example of a transistor of one embodiment of the present invention;

FIGS. 15A to 15D illustrate an example of a method for manufacturing a transistor of one embodiment of the present invention;

FIGS. 16A and 16B each illustrate a structural example of a transistor of one embodiment of the present invention;

FIGS. 17A to 17C each illustrate a structural example of a transistor of one embodiment of the present invention;

FIGS. 18A to 18C are Cs-corrected high-resolution TEM images of a cross section of a CAAC-OS and FIG. 18D is a cross-sectional schematic view of the CAAC-OS;

FIGS. 19A to 19D are Cs-corrected high-resolution TEM images of a plane of a CAAC-OS;

FIGS. 20A to 20C show structural analysis of a CAAC-OS and a single crystal oxide semiconductor by XRD;

FIGS. 21A and 21B show electron diffraction patterns of a CAAC-OS;

FIG. 22 shows a change of crystal parts of an In—Ga—Zn oxide owing to electron irradiation;

FIGS. 23A and 23B illustrate the structure of a display module of one embodiment of the present invention;

FIG. 24 illustrates the structure of a display module of one embodiment of the present invention;

FIG. 25 illustrates the structure of a display module of one embodiment of the present invention;

FIGS. 26A to 26C illustrate a method for manufacturing a display panel of an embodiment;

FIGS. 27A to 27C illustrate a method for manufacturing a display panel of an embodiment; and

FIGS. 28A and 28B illustrate the structure of a display module of one embodiment of the present invention.

### DETAILED DESCRIPTION OF THE INVENTION

Embodiments will be described in detail with reference to drawings. Note that the present invention is not limited to the description below, and it is easily understood by those skilled in the art that various changes and modifications can be made without departing from the spirit and scope of the present invention. Accordingly, the present invention should not be interpreted as being limited to the content of the embodiments below. Note that in the structures of the invention described below, the same portions or portions having similar functions are denoted by the same reference numerals in different drawings, and description of such portions is not repeated.

### Embodiment 1

In this embodiment, the structure of a display panel of one embodiment of the present invention will be described with reference to the drawings.

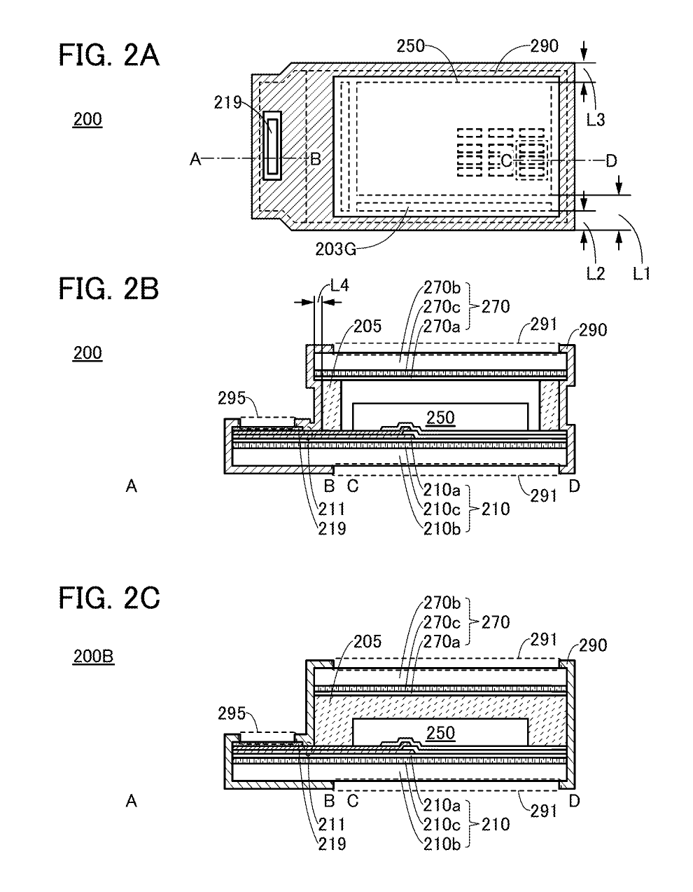

FIGS. 2A to 2C illustrate the structures of a display panel of one embodiment of the present invention. FIG. 2A is a top view of a display panel 200 which is one embodiment of the present invention. FIG. 2B is a cross-sectional view taken along the line A-B and the line C-D in FIG. 2A.

FIG. 2C is a cross-sectional view illustrating the structure of a display panel 200B which is different in structure from the display panel 200 shown in FIG. 2B.

### <Structural Example 1 of Display Panel>

The display panel 200 described in this embodiment includes a terminal 219, a first base 210 that supports the terminal 219, a second base 270 that has a region overlapping with the first base 210, a bonding layer 205 that bonds the first base 210 to the second base 270, a display element 250 that is between the first base 210 and the second base 270 and is electrically connected to the terminal 219, and an insulating layer 290 that is in contact with the first base 210, the second base 270, and the bonding layer 205. The insulating layer 290 has openings 291 and an opening 295.

The display panel 200 described in this embodiment includes the insulating layer 290 that is in contact with the first base 210 supporting the terminal 219, the second base 270 overlapping with the first base 210, and the bonding layer 205 bonding the first base 210 to the second base 270. With such a structure, diffusion of impurities into a region surrounded by the insulating layer 290 can be suppressed. Accordingly, a novel display panel with improved convenience or reliability can be provided.

The display panel 200 described in this embodiment includes the insulating layer 290 that has the openings 291 in the regions overlapping with the region where the display element 250 is placed. With such a structure, the insulating layer that suppresses diffusion of impurities can be provided in a region other than the regions overlapping with the display element 250, without the layer that absorbs light emission being formed in the regions overlapping with the display element 250. Accordingly, a novel display panel with improved reliability and lower power consumption can be provided.

The display panel 200 further includes a wiring 211 that is electrically connected to the terminal 219 and the display element 250.

The display panel 200 further includes a driver circuit 203G between the region where the display element 250 is placed and the edge of the first base 210.

In the display panel 200 described with reference to FIG. 2B, the region surrounded by the first base 210, the second base 270, and the bonding layer 205 includes a material (e.g., a gas, liquid, or liquid crystal) that is different from the bonding layer 205.

The display panel 200B described with reference to FIG. 2C is different from the display panel 200 in FIG. 2B in that the gap between the display element 250 and the second base 270 is filled with the bonding layer 205.

The display panel 200 includes the driver circuit 203G, and a distance L2 between the driver circuit 203G and the edge of the first base 210 closest to the driver circuit 203G is greater than 0 mm and less than or equal to 1.0 mm, preferably less than or equal to 0.3 mm.

In the display panel 200, a distance L1 between the display element 250, which is positioned such that the driver circuit 203G is sandwiched between the edge of the first base 210 and the display element 250, and the edge of the first base 210 closest to the display element 250 is, for example, greater than 0 mm and less than or equal to 4.0 mm, preferably less than or equal to 2 mm, more preferably less than or equal to 1.0 mm.

The display panel 200 includes the display element 250, for example, and a distance L3 between the display element 250 and the edge of the first base 210 or the edge of the second base 270 closest to the display element 250 is, for example, greater than 0 mm and less than 3.0 mm, preferably less than 1.5 mm.

The display panel 200 includes the bonding layer 205, for example, and a distance L4 which corresponds to the longer one of the following is, for example, greater than or equal to 0.3 mm, preferably greater than or equal to 0.5 mm and less than 10 mm: the distance between the edge of the region of the first base 210, overlapping with the second base 270, and the edge of the bonding layer 205; or the distance between the edge of the region of the second base 270, overlapping with the first base 210, and the edge of the bonding layer 205. The insulating layer 290 can be formed, for example, with the use of an atomic layer deposition method, making the deposition material go around and be deposited on uneven surfaces (see FIG. 2B).

Individual components included in the display panel 200 will be described below. Note that these components cannot be clearly distinguished and one component also serves as another component or include part of another component in some cases.

### <<Display Panel 200>>

The display panel 200 includes the terminal 219, the first base 210, the second base 270, the bonding layer 205, the display element 250, and the insulating layer 290.

The display panel 200 further includes the wiring 211.

### <<First Base 210>>

At least one of the first base 210 and the second base 270 has a light-transmitting region overlapping with the display element 250.

There is no particular limitation on the first base 210 as long as the first base 210 has heat resistance high enough to withstand a manufacturing process and a thickness and a size that allow the first base 210 to be placed in a manufacturing apparatus.

An organic material, an inorganic material, a composite material of an organic material and an inorganic material, or the like can be used for the first base 210. For example, an inorganic material such as glass, ceramic, or metal can be used for the first base 210.

Specifically, non-alkali glass, soda-lime glass, potash glass, crystal glass, or the like can be used for the first base 210. Specifically, an inorganic oxide film, an inorganic nitride film, an inorganic oxynitride film, or the like can be used as the first base 210. For example, a silicon oxide film, a silicon nitride film, a silicon oxynitride film, an alumina film, or the like can be used as the first base 210. SUS, aluminum, or the like can be used for the first base 210.

For example, an organic material such as a resin, a resin film, or plastic can be used for the first base 210. Specifically, a resin film or a resin plate of polyester, polyolefin, polyamide, polyimide, polycarbonate, an acrylic resin, or the like can be used as the first base 210.

For example, a composite material such as a resin film to which a metal plate, a thin glass plate, or a film of an inorganic material is attached can be used for the first base 210. For example, a composite material formed by dispersing a fibrous or particulate metal, glass, inorganic material, or the like into a resin film can be used for the first base 210. For example, a composite material formed by dispersing a fibrous or particulate resin, organic material, or the like into an inorganic material can be used for the first base 210.

Further, a single-layer material or a stacked-layer material in which a plurality of layers are stacked can be used for the first base 210. For example, a stacked-layer material in which a base, an insulating layer that prevents diffusion of impurities contained in the base, and the like are stacked can be used for the first base 210. Specifically, a stacked-layer material in which glass and one or a plurality of layers that prevent diffusion of impurities contained in the glass and that are selected from a silicon oxide layer, a silicon nitride layer, a silicon oxynitride layer, and the like are stacked can be used for the first base 210. Alternatively, a stacked-layer material in which a resin and a film that prevents diffusion of impurities passing through the resin, such as a silicon oxide film, a silicon nitride film, a silicon oxynitride film, and the like are stacked can be used for the first base 210.

A flexible material can be used for the first base 210. For example, it is possible to use a material having flexibility high enough to be bent or be folded. Specifically, it is possible to use a material which can be bent with a radius of curvature of 5 mm or more, preferably 4 mm or more, more preferably 3 mm or more, particularly preferably 1 mm or more. Further, it is possible to use a material with a thickness greater than or equal to 2.5 μm and less than or equal to 3 mm, preferably greater than or equal to 5 μm and less than or equal to 1.5 mm, more preferably greater than or equal to 10 μm and less than or equal to 500 μm, for the first base 210.

For example, a stack including a flexible base 210b, a barrier film 210a that prevents diffusion of impurities, and an adhesive layer 210c that attaches the base 210b to the barrier film 210a can be used as the first base 210.

### <<Second Base 270>>

The materials that can be used for the first base 210 can also be used for the second base 270.

For example, the second base 270 includes a flexible base 270b, a barrier film 270a that prevents diffusion of impurities, and an adhesive layer 270c that bonds the base 270b to the barrier film 270a.

### <<Bonding Layer 205>>

For the bonding layer 205, it is possible to use a material which can bond the first base 210 to the second base 270.

An inorganic material, an organic material, a composite material of an inorganic material and an organic material, or the like can be used for the bonding layer 205.

For example, glass with a melting point of 400° C. or lower, preferably 300° C. or lower can be used as the bonding layer 205.

For example, an organic material such as a thermally fusible resin or a curable resin can be used for the bonding layer 205.

For example, an organic material such as a light curable adhesive, a reactive curable adhesive, a thermosetting adhesive, and/or an anaerobic adhesive can be used for the bonding layer 205.

Specifically, an adhesive containing an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin, or the like can be used.

### <<Wiring 211 and Terminal 219>>

A conductive material can be used for the wiring 211 or the terminal 219.

For example, an inorganic conductive material, an organic conductive material, a metal material, a conductive ceramic material, or the like can be used for the wiring 211 or the terminal 219.

Specifically, a metal element selected from aluminum, gold, platinum, silver, copper, chromium, tantalum, titanium, molybdenum, tungsten, nickel, iron, cobalt, palladium, and manganese can be used for the wiring 211 or the terminal 219, for example. Alternatively, an alloy containing any of the above metal elements can be used for the wiring 211 or the terminal 219, for example. Further alternatively, an alloy in which some of the above metal elements are combined can be used for the wiring 211 or the terminal 219, for example.

Specifically, a conductive oxide such as indium oxide, indium tin oxide, indium zinc oxide, zinc oxide, or zinc oxide to which gallium is added can be used for the wiring 211 or the terminal 219, for example.

Specifically, a film containing graphene or graphite can be used for the wiring 211 or the terminal 219, for example.

For example, a film containing graphene oxide is formed and then the film containing graphene oxide is reduced, whereby a film containing graphene can be obtained. As a reducing method, a method using heat, a method using a reducing agent, or the like can be employed.

Specifically, a conducting polymer can be used for the wiring 211 or the terminal 219, for example.

### <<Display Element 250>>

A variety of display elements can be used as the display element 250.

For example, display media whose contrast, luminance, reflectivity, transmittance, or the like is changed by electrical or magnetic effect can be used as the display element.

Specifically, an electroluminescence (EL) element (e.g., an EL element including organic and inorganic materials, an organic EL element, or an inorganic EL element), an LED (e.g., a white LED, a red LED, a green LED, or a blue LED), a transistor (a transistor that emits light in response to current), an electron emitter, a liquid crystal element, electronic ink, an electrophoretic element, a grating light valve (GLV), a plasma display panel (PDP), a display element using micro electro mechanical systems (MEMS), a digital micromirror device (DMD), a digital micro shutter (DMS), MIRASOL (registered trademark), an interferometric modulator (IMOD) element, a MEMS shutter display element, an optical-interference-type MEMS display element, an electrowetting element, a piezoelectric ceramic display, a display element including a carbon nanotube, and the like can be used.

### <<Insulating Layer 290>>

The insulating layer 290 has the openings 291 in the regions overlapping with the region where the display element 250 is placed. The insulating layer 290 also has the opening 295 in a region overlapping with the terminal 219.

A film containing an oxide, a nitride, a fluoride, a ternary compound, or a polymer can be formed, for example.

Specifically, a material containing aluminum oxide, hafnium oxide, aluminum silicate, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, or the like can be used.

A material containing aluminum nitride, hafnium nitride, silicon nitride, or the like can be used, for example.

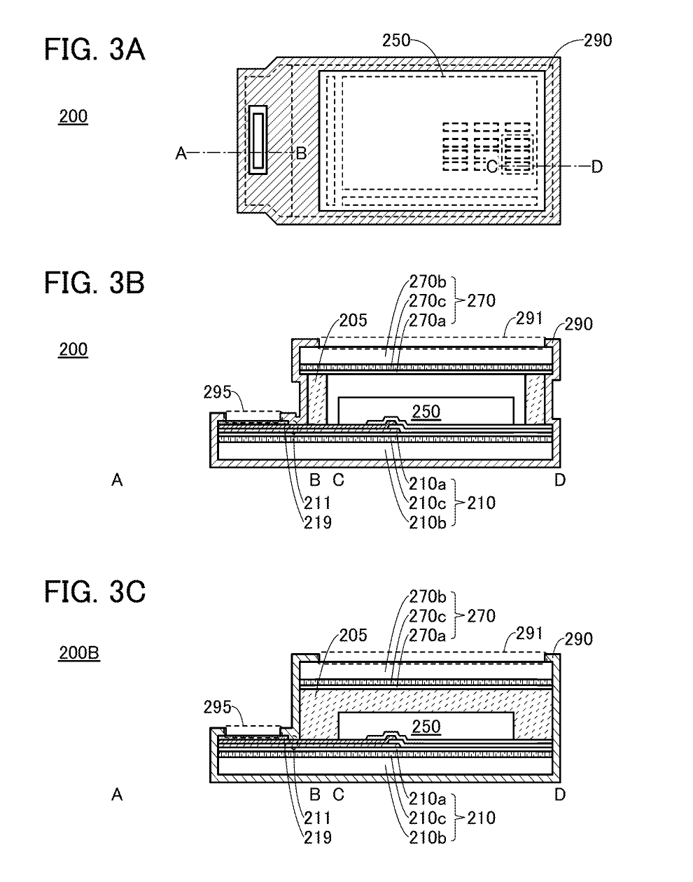

In the display panel 200 and the display panel 200B described with reference to FIGS. 2A to 2C, the openings 291 are provided in the insulating layer 290 such that the surfaces of the first base 210 and the second base 270 are exposed; however, one embodiment of the invention is not limited to such a structure. As in the display panel 200 and the display panel 200B shown in FIGS. 3A to 3C, the opening 291 may be provided in the insulating layer 290 such that the surface of the second base 270 is exposed. Alternatively, in the display panel 200 and the display panel 200B, the opening 291 may be provided in the insulating layer 290 such that the surface of the first base 210 is exposed.

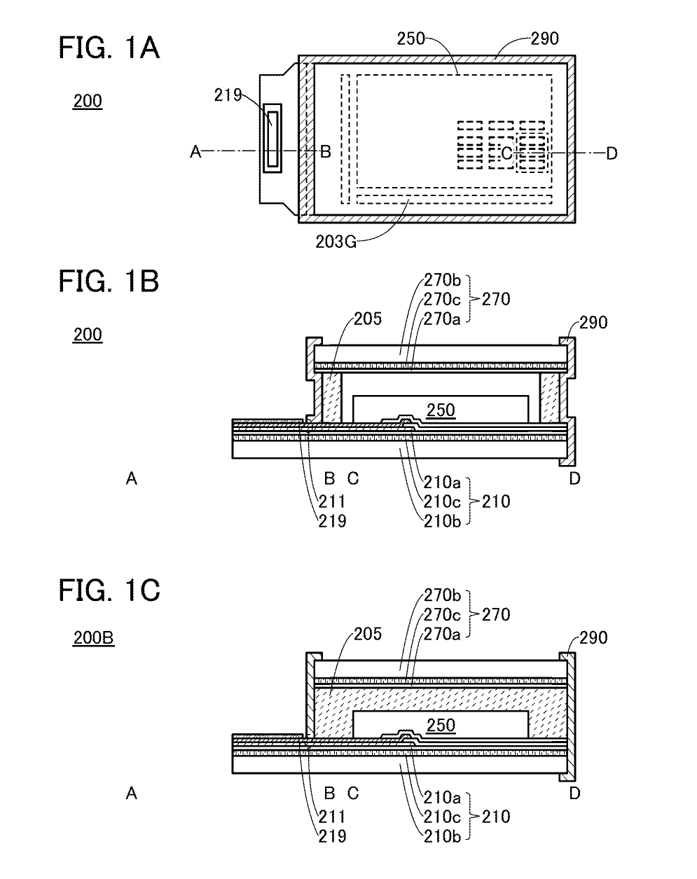

In the display panel 200 and the display panel 200B, the insulating layer 290 may be provided in a region in contact with the bonding layer 205 as shown in FIGS. 1A to 1C.

Furthermore, a mask having a function of forming the opening 295 may be provided between the insulating layer 290 and the terminal 219, instead of providing the opening 295 in the insulating layer 290. Specifically, a masking tape or the like can be used as a mask. The terminal 219 can be exposed by removing the mask when a flexible printed circuit 221 is connected to the display panel, for example.

A material having an electrically insulating property or a material having a function of suppressing impurity diffusion can be used for the insulating layer 290.

A material that hardly transmits water vapor can be used for the insulating layer 290, for example. Specifically, a material having a water vapor transmittance of 10⁻⁵ g/(m²·day) or lower, preferably 10⁻⁶ g/(m²·day) or lower can be used for the insulating layer 290.

A material that can be formed by an atomic layer deposition (ALD) method can be used for the insulating layer 290, for example.

Defects such as a crack or a pinhole in the insulating layer 290 and the uneven thickness of the insulating layer 290 may facilitate diffusion of impurities. When the insulating layer 290 is formed by an atomic layer deposition method, defects in the insulating layer 290 or the uneven thickness of the insulating layer 290 can be reduced and the insulating layer 290 can be denser. Accordingly, the insulating layer 290 capable of suppressing diffusion of impurities can be provided.

When the first base 210 or the second base 270 is separated from the other base, a minute crack (also referred to as a microcrack) may be formed on the end face. Specifically, when a piece of glass is separated from the rest in such a manner that scribing is performed and then stress is concentrated on the scribe line to cause the separation, a minute crack may be formed on the end face of the separated piece of glass. The formation of the insulating layer 290 with the use of an atomic layer deposition method can fill the minute crack formed on the end face in some cases.

An atomic layer deposition method can be used for forming the insulating layer 290. An atomic layer deposition method causes less damage to a processed member than plasma CVD or thermal CVD.

A film which contains an inorganic compound and has a thickness of greater than or equal to 3 nm and less than or equal to 200 nm, preferably greater than or equal to 5 nm and less than or equal to 50 nm can be used as the insulating layer 290.

In particular, a film which contains an inorganic compound and is formed by an atomic layer deposition method that includes a step of supplying an element containing a precursor and a step of supplying an element containing radicals, with attention being paid to favorable coverage, can be used as the insulating layer 290. In such a manner, an air or the like containing impurities such as moisture can be prevented from being in contact with the bonding layer 205.

Note that an atomic layer deposition method includes a first step of supplying a first element to the surface of a processed base and a second step of supplying a second element that reacts with the first element such that a reaction product of the first element and the second element is deposited on the surface of the processed base.

The amount of the first element adsorbed on the surface of the processed base in the first step is limited in accordance with the process condition such as temperature. Such condition may be referred to as a condition under which a self-stopping mechanism functions. Accordingly, in one cycle in which the first step and the second step are each performed once, a limited amount of the reaction product of the first element and the second element can be deposited.

For example, through repeating the first step and the second step alternately, a predetermined amount of the reaction product of the first element and the second element can be deposited on the surface of the processed base.

A step of removing the first element which is supplied in surplus in the first step may be performed after the first step.

A step of removing the second element which is supplied in surplus in the second step may be performed after the second step.

Specifically, in the first step, the first element is supplied to a reaction chamber in which a processed base is placed and a predetermined environment is prepared. Through this step, the first element is adsorbed on the surface of the processed base.

Next, the surplus first element that remains in the reaction chamber is purged out of the reaction chamber while a purge gas is supplied thereto.

In the second step, the second element is supplied. Then, the first element adsorbed on the surface of the processed base reacts with the second element, whereby a reaction product is deposited over the surface of the processed base.

Next, the surplus second element that remains in the reaction chamber is purged out of the reaction chamber while a purge gas is supplied thereto.

After that, the first step and the second step are repeated, whereby a predetermined amount of the reaction product is deposited over the processed base.

A precursor or the like which is selected in accordance with the kind of reaction product to be deposited can be used as the first element. Specifically, a volatile organic metal compound, metal alkoxide, or the like can be used as the first element.

For example, a precursor that is vaporized with the use of a vaporizing apparatus (also referred to as a vaporizer or a bubbling apparatus) can be used as the first element.

A material containing a plurality of elements can be used as the first element. Furthermore, materials used as the first element may be different in the repeated first steps.

A variety of materials, selected in accordance with the kind of reaction product to be deposited and the first element, which react with the first element can be used as the second element, for example. A material that contributes to an oxidation reaction, a reduction reaction, an addition reaction, a decomposition reaction, a hydrolysis reaction, or the like, for example, can be used as the second element.

Plasma, e.g., oxygen radicals or nitrogen radicals, can be used as the second element, in which case the rate of reaction with the first element can be increased. As a result, the temperature rise of the processed base can be suppressed or the deposition time can be shortened.

### <Structural Example 2 of Display Panel>

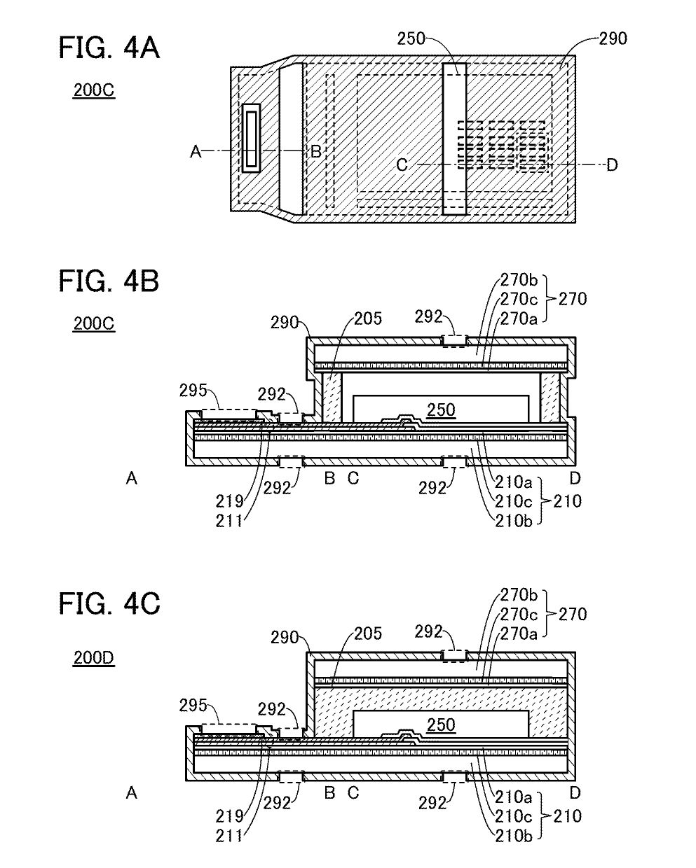

Another structure of a display panel of one embodiment of the present invention will be described with reference to FIGS. 4A to 4C.

FIGS. 4A to 4C illustrate the structures of a display panel of one embodiment of the present invention. FIG. 4A is a top view of a display panel 200C of one embodiment of the present invention. FIG. 4B is a cross-sectional view taken along the line A-B and the line C-D in FIG. 4A.

FIG. 4C is a cross-sectional view illustrating the structure of a display panel 200D which is different in structure from the display panel 200C shown in FIG. 4B.

In the display panel 200C, the positions of openings provided in the insulating layer 290 are different from those in the display panel 200 described with reference to FIGS. 2A and 2B. Different structures will be described in detail below, and the above description is referred to for the other similar structures.

The display panel 200C described in this embodiment corresponds to the above-described display panel except that the insulating layer 290 has openings 292 and the opening 295. The base 210b and the base 270b are flexible.

The display panel 200C described in this embodiment is configured such that the insulating layer 290 has the openings 292 in the regions overlapping with the wiring 211. With such a structure, flexibility of the display panel 200C in the regions where the openings 292 are positioned can be increased as compared with other regions. Accordingly, a novel display panel of which mountability on a housing and reliability are excellent can be provided.

### <<Display Panel 200C>>

The display panel 200C includes the terminal 219, the first base 210, the second base 270, the bonding layer 205, the display element 250, and the insulating layer 290.

The display panel 200C further includes the wiring 211.

The insulating layer 290 has the openings 292 in the regions overlapping with the wiring 211.

The insulating layer 290 may have the openings 292 in the regions overlapping with part of the region where the display element 250 is placed. For example, the opening 292 in a belt-like shape that includes the line bisecting the region where the display element 250 is placed may be provided (see FIG. 4B). Alternatively, for example, the openings 292 in belt-like shapes that include the lines trisecting the region where the display element 250 is placed may be provided.

### <Structural Example 3 of Display Panel>

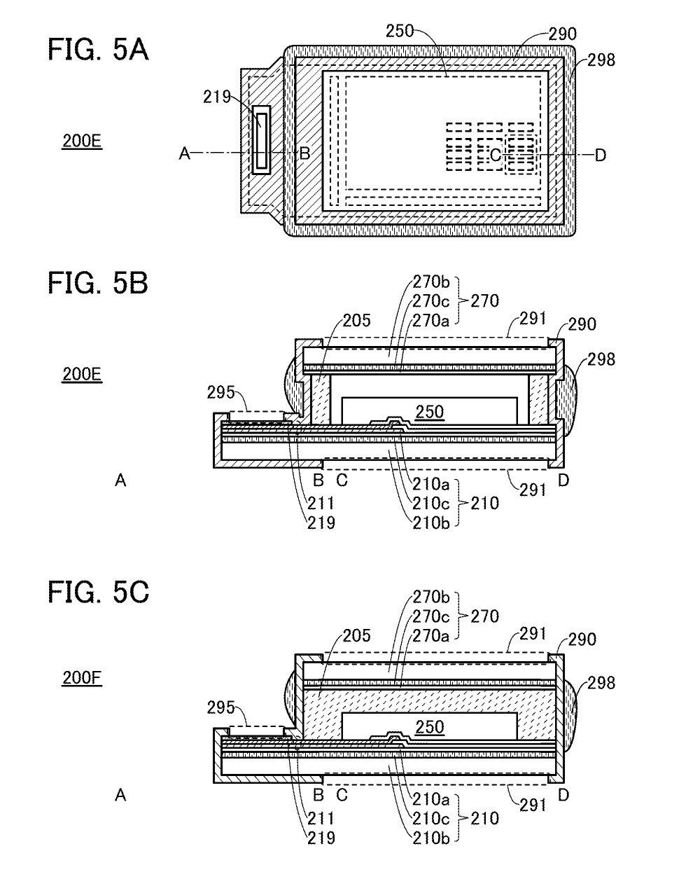

Another structures of a display panel of one embodiment of the present invention will be described with reference to FIGS. 5A to 5C.

FIGS. 5A to 5C illustrate the structures of a display panel of one embodiment of the present invention. FIG. 5A is a top view of a display panel 200E of one embodiment of the present invention. FIG. 5B is a cross-sectional view taken along the line A-B and the line C-D in FIG. 5A.

FIG. 5C is a cross-sectional view illustrating the structure of a display panel 200F which is different in structure from the display panel 200E shown in FIG. 5B.

The display panel 200E is different from the display panel 200 described with reference to FIGS. 2A and 2B in that a resin layer 298 is provided. Different structures will be described in detail below, and the above description is referred to for the other similar structures.

The display panel 200E described in this embodiment corresponds to the above-described display panel except that the resin layer 298 is provided. The insulating layer 290 has a region that is sandwiched between the bonding layer 205 and the resin layer 298.

The display panel 200E described in this embodiment includes the insulating layer 290 that is sandwiched between the bonding layer 205 and the resin layer 298. Such a structure makes it possible to disperse a variety of stresses, whereby damage to the insulating layer due to the concentration of the stresses can be prevented. Accordingly, a novel display module with improved convenience or reliability can be provided.

### <<Display Panel 200E>>

The display panel 200E includes the resin layer 298, the terminal 219, the first base 210, the second base 270, the bonding layer 205, the display element 250, and the insulating layer 290.

The display panel 200E further includes the wiring 211.

### <<Resin Layer 298>>

The display panel 200E includes the resin layer 298 that is positioned such that the insulating layer 290 has a region sandwiched between the bonding layer 205 and the resin layer 298.

Materials similar to the materials that can be used for the bonding layer 205, for example, can be used for the resin layer 298.

This embodiment can be combined with any of the other embodiments in this specification as appropriate.

### Embodiment 2

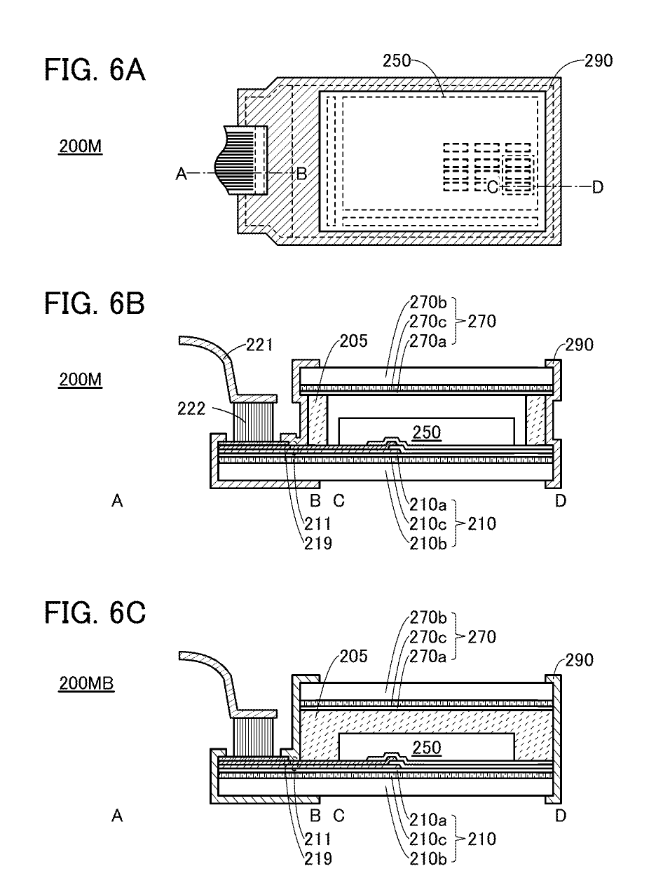

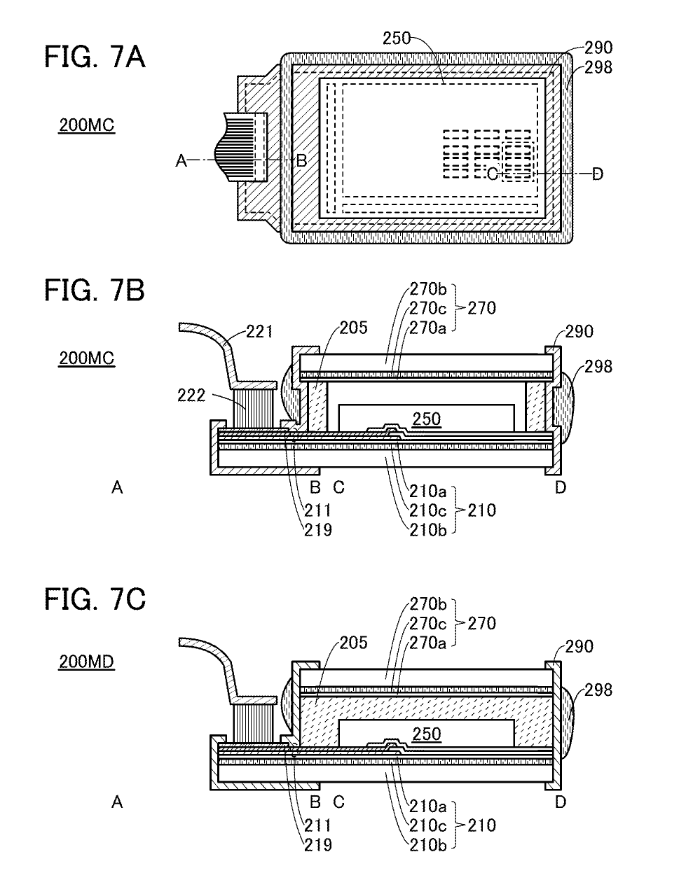

In this embodiment, the structures of a display module of one embodiment of the present invention will be described with reference to FIGS. 6A to 6C and FIGS. 7A to 7C.

FIGS. 6A to 6C illustrate the structures of a display module of one embodiment of the present invention. FIG. 6A is a top view of a display module 200M of one embodiment of the present invention. FIG. 6B is a cross-sectional view taken along the line A-B and the line C-D in FIG. 6A.

FIG. 6C is a cross-sectional view illustrating the structure of a display module 200 MB which is different in structure from the display module 200M shown in FIG. 6B.

### <Structural Example 1 of Display Module>

The display module 200M described in this embodiment includes a terminal 219, a first base 210 that supports the terminal 219, a second base 270 that has a region overlapping with the first base 210, a bonding layer 205 that bonds the first base 210 to the second base 270, a display element 250 that is between the first base 210 and the second base 270 and is electrically connected to the terminal 219, a flexible printed circuit 221 that is electrically connected to the terminal 219, and an insulating layer 290 that is in contact with the first base 210, the second base 270, and the bonding layer 205.

The display module 200M described in this embodiment includes: the insulating layer 290 that is in contact with the first base 210 supporting the terminal 219, the second base 270 overlapping with the first base 210, and the bonding layer 205 bonding the first base 210 to the second base 270; and the flexible printed circuit 221 electrically connected to the terminal 219. With such a structure, diffusion of impurities into a region surrounded by the insulating layer 290 can be suppressed. Accordingly, a novel display panel with improved convenience or reliability can be provided.

The display module 200M further includes a wiring 211 that is electrically connected to the terminal 219 and the display element 250.

The display module 200M described with reference to FIG. 6B includes, between the display element 250 and the second base 270, a region that includes a material different from the bonding layer 205. The region contains a gas, for example.

The display module 200 MB described with reference to FIG. 6C is different from the display module 200M in FIG. 6B in that the bonding layer 205 is present between the display element 250 and the second base 270.

The display module 200M is different from the display panel 200 described with reference to FIGS. 2A and 2B in that the flexible printed circuit 221 and an anisotropic conductive film 222 are provided. Different structures will be described in detail below, and the above description is referred to for the other similar structures.

### <<Flexible Printed Circuit 221>>

The flexible printed circuit 221 includes a wiring that is electrically connected to the terminal 219, a base that supports the wiring, and a coating layer that has a region overlapping with the wiring. The wiring has a region that is sandwiched between the base and the coating layer and a region that does not overlap with the coating layer.

The region of the wiring not overlapping with the coating layer can be used as a terminal of the flexible printed circuit 221.

A conductive material can be used for the wiring of the flexible printed circuit 221. For example, the materials that can be used for the wiring 211 or the like can be used for the wiring of the flexible printed circuit 221. Specifically, copper or the like can be used.

A material that has an insulating region in the region in contact with the wiring of the flexible printed circuit 221 can be used as the base of the flexible printed circuit 221.

For example, an organic material such as a resin, a resin film, or plastic can be used for the base. Specifically, a resin layer, film, or plate of polyester, polyolefin, polyamide, polyimide, polycarbonate, an acrylic resin, or the like can be used as the base. A stretched film of which the glass transition temperature is greater than or equal to 150° C., preferably greater than or equal to 200° C., more preferably greater than or equal to 250° C. can be used for the base.

The anisotropic conductive film 222 can be used as a material for electrically connecting the flexible printed circuit 221 to the terminal 219. A material containing conductive particles, a resin, and the like can be used for the anisotropic conductive film 222, in which case the terminal of the flexible printed circuit 221 and the terminal 219 can be electrically connected to each other via the conductive particles and the like.

### <Structural Example 2 of Display Module>

Another structures of a display module of one embodiment of the present invention will be described with reference to FIGS. 7A to 7C.

FIGS. 7A to 7C illustrate the structures of a display module of one embodiment of the present invention. FIG. 7A is a top view of a display module 200MC of one embodiment of the present invention. FIG. 7B is a cross-sectional view taken along the line A-B and the line C-D in FIG. 7A.

FIG. 7C is a cross-sectional view illustrating the structure of a display module 200MD which is different in structure from the display module 200MC shown in FIG. 7B.

The display module 200MC is different from the display module 200M described with reference to FIGS. 6A and 6B in that a resin layer 298 is provided. Different structures will be described in detail below, and the above description is referred to for the other similar structures.

The display module 200MC described in this embodiment corresponds to the above-described display module except that the resin layer 298 is provided. The insulating layer 290 has a region that is sandwiched between the bonding layer 205 and the resin layer 298.

The display module 200MC described in this embodiment includes the insulating layer 290 that is sandwiched between the bonding layer 205 and the resin layer 298. Such a structure makes it possible to disperse a variety of stresses, whereby damage to the insulating layer due to the concentration of the stresses can be prevented. Accordingly, a novel display module with improved convenience or reliability can be provided.

### <<Display Module 200MC>>

The display module 200MC includes the resin layer 298, the terminal 219, the first base 210, the second base 270, the bonding layer 205, the display element 250, the flexible printed circuit 221, or the insulating layer 290.

The display module 200MC further includes the wiring 211.

### <<Resin Layer 298>>

The resin layer 298, which is positioned such that the insulating layer 290 has a region sandwiched between the bonding layer 205 and the resin layer 298, is provided.

Materials similar to the materials that can be used for the bonding layer 205, for example, can be used for the resin layer 298.

This embodiment can be combined with any of the other embodiments in this specification as appropriate.

### Embodiment 3

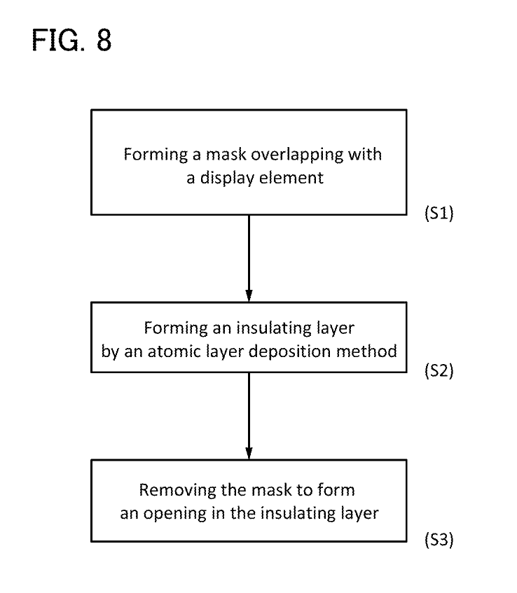

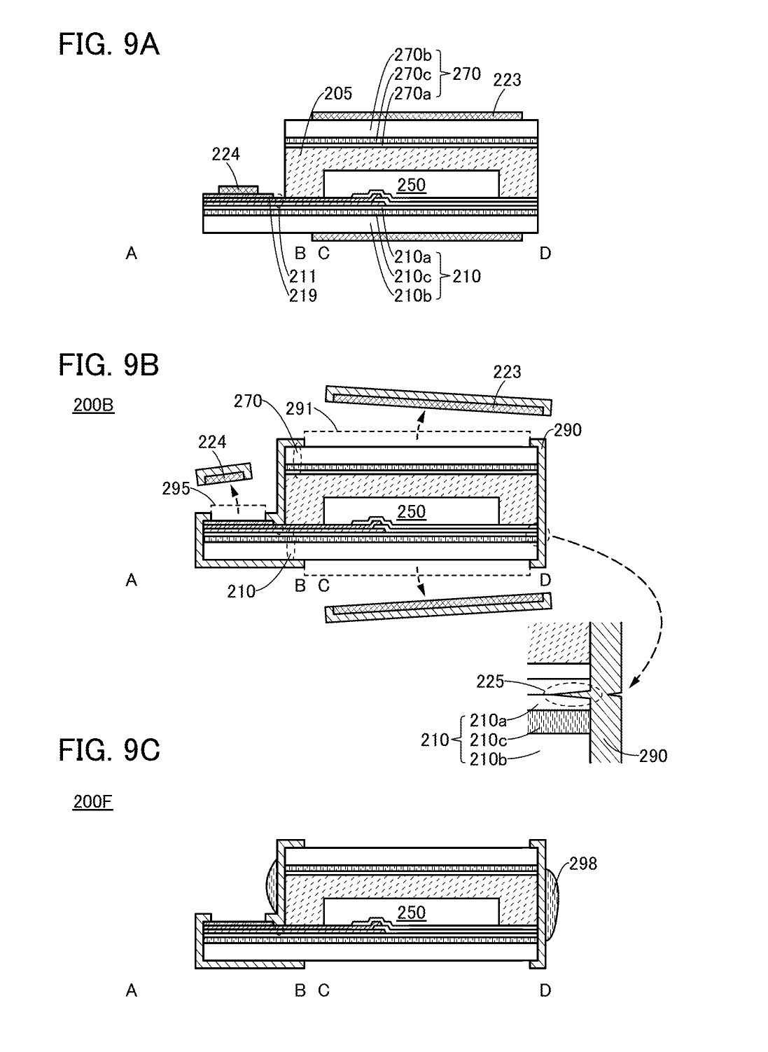

In this embodiment, methods for manufacturing a display panel of one embodiment of the present invention will be described with reference to FIG. 8, FIGS. 9A to 9C, FIGS. 10A and 10B, and FIGS. 11A and 11B.

FIG. 8 is a flow chart illustrating a method for manufacturing a display panel of one embodiment of the present invention.

FIGS. 9A to 9C illustrate a method for manufacturing a display panel of one embodiment of the present invention. Specifically, FIGS. 9A to 9C are cross-sectional views of the display panels during the manufacturing process.

### <<Example 1 of Method for Manufacturing Display Panel>>

A method for manufacturing a display panel described in this embodiment includes the following three steps (see FIG. 8).

### <<First Step>>

In a first step, a processed member that includes the following components is prepared: the terminal 219, the first base 210 that supports the terminal 219, the second base 270 that has a region overlapping with the first base 210, the bonding layer 205 that bonds the first base 210 to the second base 270, and the display element 250 which is between the first base 210 and the second base 270 and is electrically connected to the terminal 219; then, masks 223 are formed in regions overlapping with the region where the display element 250 is placed such that the masks 223 are each in contact with the first base 210 or the second base 270 (see FIG. 8 (S1) and FIG. 9A).

In the first step, a mask 224 may be formed in a region overlapping with the terminal 219.

### <<Second Step>>

In the second step, the insulating layer 290 that is in contact with the first base 210, the second base 270, the bonding layer 205, and the terminal 219 is formed with the use of an atomic layer deposition method (See FIG. 8 (S2)).

In the case where the mask 224 covers the entire exposed surface of the terminal 219, the insulating layer 290 is not formed on the terminal 219 in the second step.

Defects such as a crack or a pinhole in the insulating layer 290 and the uneven thickness of the insulating layer 290 may facilitate diffusion of impurities. When the insulating layer 290 is formed by an atomic layer deposition method, defects in the insulating layer 290 or the uneven thickness of the insulating layer 290 can be reduced and the insulating layer 290 can be denser. Accordingly, the insulating layer 290 capable of suppressing diffusion of impurities can be provided.

When the first base 210 or the second base 270 is separated from another base, a minute crack (also referred to as a microcrack 225) may be formed on the end face. Specifically, when a piece of glass is separated from the rest (the separating process is also referred to as breaking) in such a manner that scribing is performed and then stress is concentrated on the scribe line to cause the separation, a minute crack may be formed on the end face of the separated piece of glass. The formation of the insulating layer 290 with the use of an atomic layer deposition method can fill the minute crack formed on the end face in some cases (see FIG. 9B).

The insulating layer 290 can be formed by an atomic layer deposition method, using a deposition apparatus 190 that will be described in Embodiment 4, for example.

### <<Third Step>>

In the third step, portions of the insulating layer 290 are removed together with the masks 223, whereby the openings 291 are formed in the insulating layer 290 in the regions overlapping with the display element 250 (see FIG. 8 (S3) and FIG. 9B).

In the case where the mask 224 is provided over the terminal 219, a portion of the insulating layer 290 is removed together with the mask 224 in the third step, whereby the opening 295 is formed in the insulating layer 290 in the region overlapping with the terminal 219.

The method for manufacturing a display panel described in this embodiment includes the first step of forming the masks 223 in the regions overlapping with the display element 250, the second step of forming the insulating layer 290 by an atomic layer deposition method, and the third step of forming the openings 291 in the insulating layer 290 in the regions overlapping with the display element 250. Through such a method, an insulating layer having openings in regions overlapping with a display element can be formed. Accordingly, a method for manufacturing a novel display panel with improved reliability can be provided.

### <Modification Example of Method for Manufacturing Display Panel>

A method for manufacturing a display panel described in this embodiment includes, in addition to the above-described steps, a fourth step.

### <<Fourth Step>>

In the fourth step, the resin layer 298 is formed such that the insulating layer 290 has a region sandwiched between the bonding layer 205 and the resin layer 298 (see FIG. 9C).

### <Example 2 of Method for Manufacturing Display Panel>

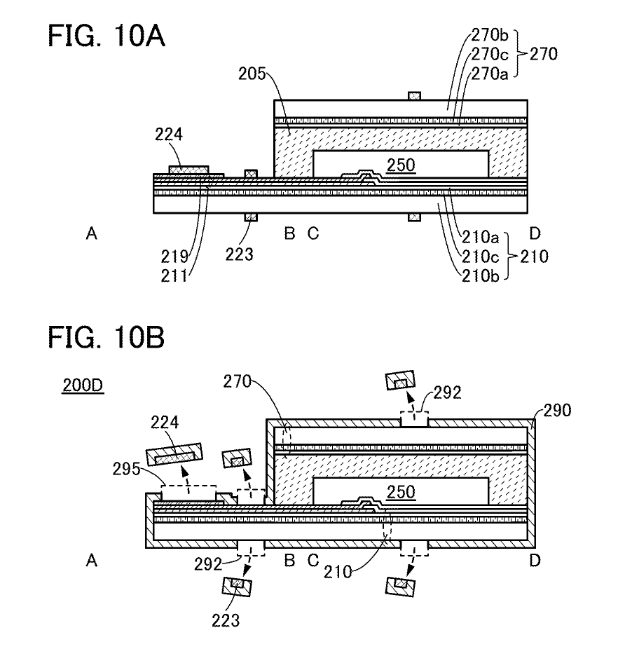

Another example of a method for manufacturing a display panel of one embodiment of the present invention will be described with reference to FIGS. 10A and 10B.

FIGS. 10A and 10B illustrate a method for manufacturing a display panel of one embodiment of the present invention. Specifically, FIGS. 10A and 10B are cross-sectional views of the display panel during the manufacturing process.

In the manufacturing method described with reference to FIGS. 10A and 10B, the regions where the masks 223 are formed are different from those in the manufacturing method described with reference to FIGS. 9A and 9B. Here, the difference will be described in detail, and the above description is referred to for the part of the manufacturing method to which a method similar to the above can be applied.

### <<First Step>>

In a first step, the processed member that includes the following is prepared: the terminal 219, the first base 210 that supports the terminal 219, the second base 270 that has a region overlapping with the first base 210, the bonding layer 205 that bonds the first base 210 to the second base 270, and the display element 250 which is between the first base 210 and the second base 270 and is electrically connected to the terminal 219; then, the masks 223 are formed in regions overlapping with the wiring 211 such that the masks 223 are each in contact with the first base 210 or the second base 270 (see FIG. 8 (S1) and FIG. 10A).

In the first step, the masks 223 may be formed in regions overlapping with part of the region where the display element 250 is placed. For example, the mask 223 may be formed in a belt-like shape that includes the line bisecting the region where the display element 250 is placed (see FIG. 10A). Alternatively, for example, the masks 223 may be formed in belt-like shapes that include the lines trisecting the region where the display element 250 is placed.

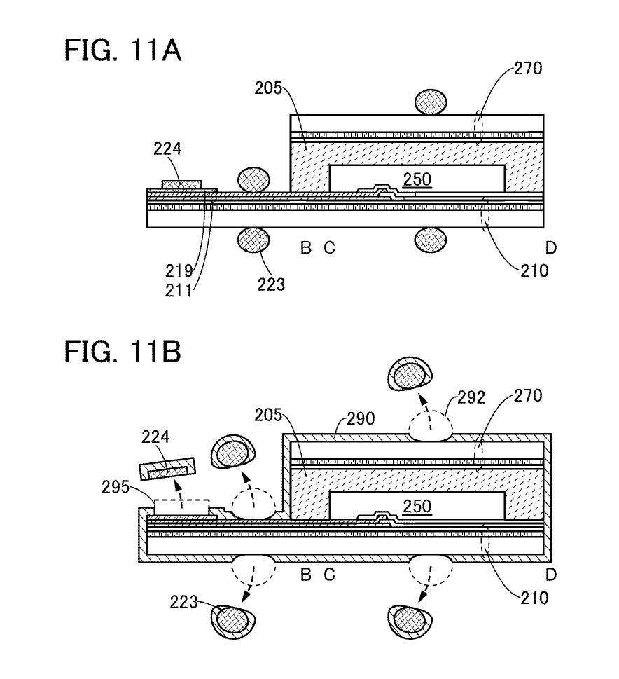

The cross-sectional shape of the mask 223 is not limited to a rectangle. When the angle between the side surface of the mask 223 and the surface of a film (here, the first base 210 or the second base 270) in the cross-sectional view of the area where the end portion of the mask 223 is in contact with the film is larger than 90°, the end portion of the insulating layer 290 can have a tapered shape. As a result, the adhesion of the insulating layer 290 to the first base 210 or the second base 270 can be improved. The cross-sectional shape of the mask 223 may be a circle or an ellipse, for example (see FIGS. 11A and 11B).

This embodiment can be combined with any of the other embodiments in this specification as appropriate.

### Embodiment 4

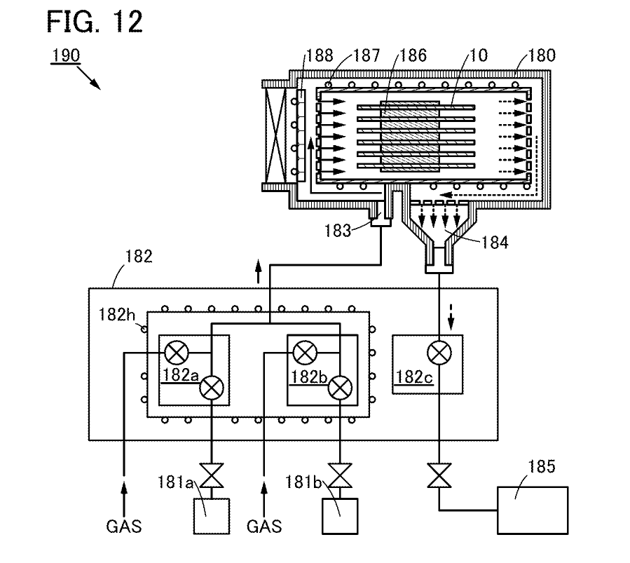

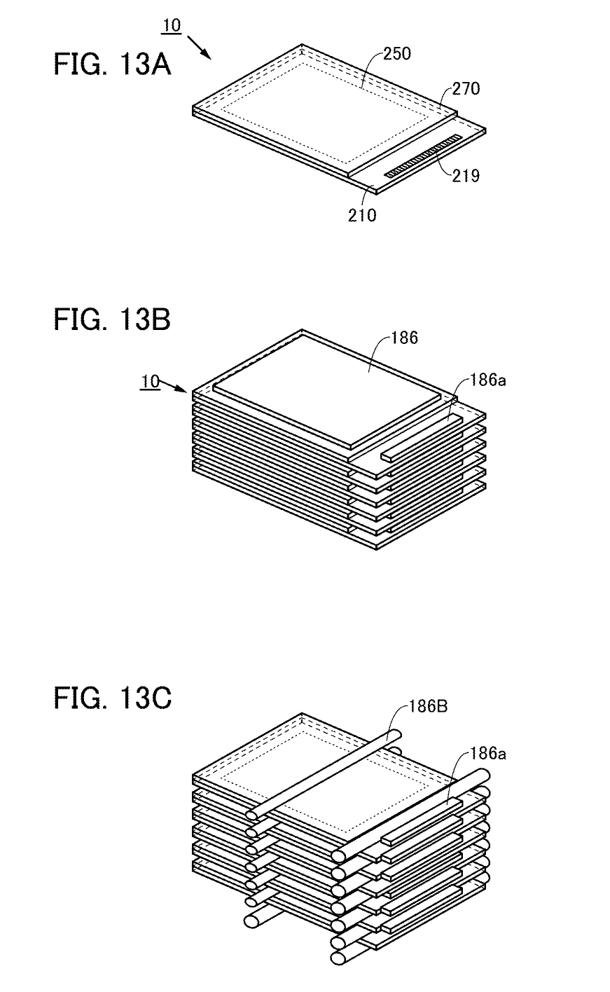

In this embodiment, a film formation apparatus that can be used for manufacturing a display module of one embodiment of the present invention will be described with reference to FIG. 12 and FIGS. 13A to 13C.

FIG. 12 is a cross-sectional view illustrating the deposition apparatus 190 that can be used for manufacturing a display module of one embodiment of the present invention.

FIG. 13A is a perspective view of a processed member 10 that can be used for manufacturing a display module of one embodiment of the present invention.

FIG. 13B illustrates a state in which the processed member 10 that can be used for manufacturing a display module of one embodiment of the present invention is supported by a support 186.

### <Structural Example of Deposition Apparatus 190>

The deposition apparatus 190 described in this embodiment includes a deposition chamber 180 and a control portion 182 connected to the deposition chamber 180.

The control portion 182 includes a control unit (not illustrated) which supplies control signals and flow rate controllers 182a, 182b, and 182c to which the control signals are supplied. For example, high-speed valves can be used as the flow rate controllers. Specifically, flow rates can be precisely controlled by using ALD valves or the like. The control portion 182 also includes a heating mechanism 182h which controls the temperatures of the flow rate controllers and pipes.

The flow rate controller 182a is supplied with a control signal, a first source material, and an inert gas and has a function of supplying the first source material or the inert gas in accordance with the control signal.

The flow rate controller 182b is supplied with a control signal, a second source material, and an inert gas and has a function of supplying the second source material or the inert gas in accordance with the control signal.

The flow rate controller 182c is supplied with a control signal and has a function of connecting to an evacuation unit 185 in accordance with the control signal.

### <<Source Material Supply Portion>>

A source material supply portion 181a has a function of supplying the first source material and is connected to the flow rate controller 182a.

A source material supply portion 181b has a function of supplying the second source material and is connected to the flow rate controller 182b.

A vaporizer, a heating unit, or the like can be used as each of the source material supply portions. Thus, a gaseous source material can be generated from a solid or liquid source material.

Note that the number of source material supply portions is not limited to two and may be three or more.

### <<Source Material>>

Any of a variety of materials can be used as the first source material.

For example, a volatile organometallic compound, a volatile metal alkoxide, or the like can be used as the first source material.

Any of a variety of materials which react with the first source material can be used as the second source material. For example, a material which contributes to an oxidation reaction, a material which contributes to a reduction reaction, a material which contributes to an addition reaction, a material which contributes to a decomposition reaction, a material which contributes to a hydrolysis reaction, or the like can be used as the second source material.

Furthermore, a material containing a radical can be used as the second source material. For example, a material in a plasma state which is obtained by supplying the material to a plasma source can be used as the second source material. Specifically, an oxygen radical, a nitrogen radical, or the like can be used as the second source material.

The second source material is preferably a material which reacts with the first source material at a temperature close to room temperature. For example, a material which reacts at a temperature higher than or equal to room temperature and lower than or equal to 200° C., preferably higher than or equal to 50° C. and lower than or equal to 150° C., is preferable.

### <<Evacuation Unit 185>>

The evacuation unit 185 has an evacuating function and is connected to the flow rate controller 182c. Note that a trap for capturing the material to be evacuated may be provided between an outlet port 184 and the flow rate controller 182c.

### <<Control Portion 182>>

The control unit supplies the control signals for controlling the flow rate controllers, a control signal for controlling the heating mechanism, or the like. For example, in a first step, the first source material is supplied to a surface of a processed base. Then, in a second step, the second source material which reacts with the first source material is supplied. Accordingly, a reaction product of the first source material and the second source material can be deposited onto a surface of the processed member 10.

Note that the amount of the reaction product to be deposited onto the surface of the processed member 10 can be controlled by a repetition of the first step and the second step.

Note that the amount of the first source material to be supplied to the processed member 10 is limited by the maximum possible amount of adsorption on the surface of the processed member 10. For example, conditions are selected so that a monomolecular layer of the first source material is formed on the surface of the processed member 10, and the formed monomolecular layer of the first source material is reacted with the second source material, whereby a significantly uniform layer containing the reaction product of the first source material and the second source material can be formed.

Accordingly, a variety of materials can be deposited on a surface of the processed member 10 even when the surface has a complicated structure. For example, a film having a thickness greater than or equal to 3 nm and less than or equal to 200 nm can be formed on the processed member 10.

In the case where, for example, a small hole called a pinhole or the like is formed in the surface of the processed member 10, the pinhole can be filled by depositing a material into the pinhole.

The remainder of the first source material or the second source material is evacuated from the deposition chamber 180 with use of the evacuation unit 185. For example, the evacuation may be performed while an inert gas such as argon or nitrogen is introduced.

### <<Deposition Chamber 180>>

The deposition chamber 180 includes an inlet port 183 from which the first source material, the second source material, and the inert gas are supplied and the outlet port 184 from which the first source material, the second source material, and the inert gas are evacuated.

The deposition chamber 180 includes a support 186 which has a function of supporting one or a plurality of processed members 10, a heating mechanism 187 which has a function of heating the one or plurality of processed members, and a door 188 which has a function of opening or closing to load and unload the one or plurality of processed members 10.

For example, a resistive heater, an infrared lamp, or the like can be used as the heating mechanism 187.

The heating mechanism 187 has a function of heating up, for example, to 80° C. or higher, 100° C. or higher, or 150° C. or higher.

The heating mechanism 187 heats the one or plurality of processed members 10 to a temperature higher than or equal to room temperature and lower than or equal to 200° C., preferably higher than or equal to 50° C. and lower than or equal to 150° C.

The deposition chamber 180 also includes a pressure regulator and a pressure detector.

### <<Support 186>>

The support 186 supports the processed member 10.

A state in which six processed members 10 are supported with the use of seven supports 186, for example, is shown in FIG. 12 and FIG. 13B.

The outer shape of the support 186 is larger than the region where the display element 250 is placed and is smaller than the processed member 10, for example.

Examples of the material used for the support 186 include plastic, metal, alloy, paper, and glass. The use of materials of which surfaces have weak adhesion (e.g., a low adhesion sheet, a silicone sheet, and a rubber sheet) for the support 186 enables the processed member 10 to be placed between the supports 186 tightly.

On one processed member 10 that is supported by one support 186, another support 186 is placed such that another processed member 10 can be supported thereon. In this manner, the supports 186 and the processed members 10 are alternately stacked on one another, whereby a plurality of processed members can be set in the deposition chamber 180.

The processed member 10 is placed on the support 186 of which the outer shape is smaller than that of the processed member 10 such that the edges of the processed member 10 extend out of the support 186. In this manner, a source material can be uniformly supplied to the edges of the processed member 10 and its sides (see FIG. 13B).

Furthermore, the processed member 10 is placed such that its edges are not in contact with the wall surface of the deposition chamber 180. For example, the distance between the edge of the processed member 10 and the wall surface of the deposition chamber 180 is set longer than the space between one processed member 10 and another processed member 10, whereby the source material can be supplied uniformly.

The support 186 may have a structure that allows the single support 186 to be placed independently, or may be provided with a beam that connects a plurality of supports 186.

A mask 186a may be placed in a position overlapping with the terminal 219. The mask 186a may have a structure that allows the mask 186a to be placed independently, or may be connected to one support 186. Materials similar to the materials for the support 186 can be used for the mask 186a, for example.

As shown in FIG. 13C, a support 186B having a circular or elliptic cross section may be used instead of the support 186. Examples of the material used for the support 186B include plastic, metal, alloy, and glass.

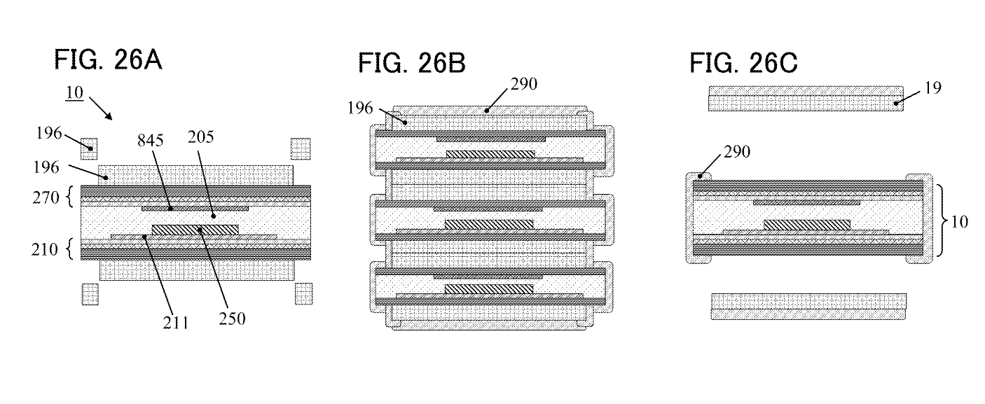

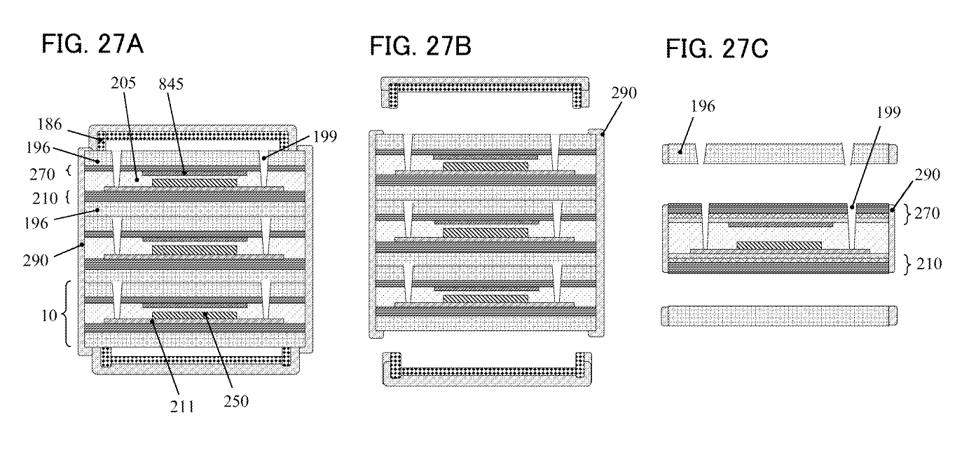

Alternatively, as shown in FIGS. 26A to 26C and FIGS. 27A to 27C, a separate film 196 may be used instead of the support 186. The separate film 196 is provided on each of the top and bottom surfaces of the processed member 10. The separate film 196 has a function of protecting the surfaces of the processed member 10. The outer shape of the separate film 196 may be the same as the outer shape of the processed member 10. Alternatively, the separate film 196 may be processed to be smaller than the outer shape of the processed member 10 such that the edges of the processed member 10 extend out of the separate film 196 (see FIG. 26A). The processed member 10 shown in FIG. 26A includes the first base 210, the second base 270, the bonding layer 205, the wiring 211 including a terminal, the display element 250, the separate film 196, and a coloring layer 845. A plurality of processed members 10 are stacked and the insulating layer 290 is deposited (see FIG. 26B), and then, the separate films 196 are removed, whereby the insulating layer 290 in the region in contact with the first base 210, the second base 270, and the bonding layer 205 can be formed as shown in FIG. 26C. In the case where the separate film 196 and the processed member 10 have an opening 199, the support 186 may be provided on each of the top of bottom of the stack including a plurality of processed members 10 to overlap with the separate films 196 (see FIG. 27A). The insulating layer 290 is deposited after the supports 186 are provided as shown in FIG. 27A, and then, the supports 186 are removed (see FIG. 27B), and the separate films 196 are removed, whereby the insulating layer 290 can be formed only on the side surfaces of the processed member 10 having the opening 199 as shown in FIG. 27C. Note that part of the first base 210 and the second base 270 is not illustrated in FIG. 26B and FIGS. 27A and 27B.

### <Example of Film>

Films which can be formed using the deposition apparatus 190 described in this embodiment will be described.

For example, a film containing an oxide, a nitride, a fluoride, a sulfide, a ternary compound, a metal, or a polymer can be formed.

For example, a material containing aluminum oxide, hafnium oxide, aluminum silicate, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, or the like can be used.

For example, a material containing aluminum nitride, hafnium nitride, silicon nitride, tantalum nitride, titanium nitride, niobium nitride, molybdenum nitride, zirconium nitride, gallium nitride, or the like can be used.

For example, a material containing copper, platinum, ruthenium, tungsten, iridium, palladium, iron, cobalt, nickel, or the like can be used.

For example, a material containing zinc sulfide, strontium sulfide, calcium sulfide, lead sulfide, calcium fluoride, strontium fluoride, zinc fluoride, or the like can be used.

For example, a material that includes a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like can be used.

### <<Film Containing Aluminum Oxide>>

For example, a gas obtained by vaporizing a material containing an aluminum precursor compound can be used as the first source material. Specifically, trimethylaluminum (TMA, or Al(CH₃)₃ (chemical formula)), tris(dimethylamide)aluminum, triisobutylaluminum, and aluminum tris(2,2,6,6-tetramethyl-3,5-heptanedionate), or the like can be used.

Water vapor (H₂O (chemical formula)) can be used as the second source material.

With the use of the deposition apparatus 190, a film containing aluminum oxide can be formed from the first source material and the second source material.

### <<Film Containing Hafnium Oxide>>

For example, a gas obtained by vaporizing a material containing a hafnium precursor compound can be used as the first source material. Specifically, a material containing hafnium amide such as tetrakis(dimethylamide)hafnium (TDMAH, or Hf[N(CH₃)₂]₄ (chemical formula)) or tetrakis(ethylmethylamide)hafnium can be used.

Ozone can be used as the second source material.

### <<Film Containing Tungsten>>

For example, a WF₆ gas can be used as the first source material.

A B₂H₆ gas, a SiH₄ gas, or the like can be used as the second source material.

This embodiment can be combined with any of the other embodiments in this specification as appropriate.

### Embodiment 5

In this embodiment, a structural example of a transistor that can be used in pixels of a display module to be described later will be described with reference to drawings.

### <Structural Example of Transistor>

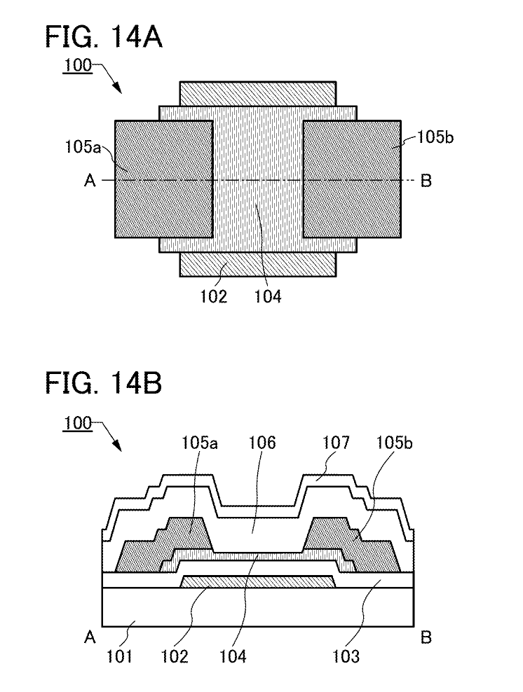

FIG. 14A is a schematic top view of a transistor 100 described below as an example. FIG. 14B is a schematic cross-sectional view of the transistor 100 taken along the section line A-B in FIG. 14A. The transistor 100 illustrated as an example in FIGS. 14A and 14B is a bottom-gate transistor.

The transistor 100 includes a gate electrode 102 over a substrate 101, an insulating layer 103 over the substrate 101 and the gate electrode 102, an oxide semiconductor layer 104 over the insulating layer 103, which overlaps with the gate electrode 102, and a pair of electrodes 105a and 105b in contact with the top surface of the oxide semiconductor layer 104. Further, an insulating layer 106 is provided to cover the insulating layer 103, the oxide semiconductor layer 104, and the pair of electrodes 105a and 105b, and an insulating layer 107 is provided over the insulating layer 106.

### <<Substrate>>

There is no particular limitation on the property of a material and the like of the substrate 101 as long as the material has heat resistance enough to withstand at least heat treatment which will be performed later. For example, a glass substrate, a ceramic substrate, a quartz substrate, a sapphire substrate, or an yttria-stabilized zirconia (YSZ) substrate may be used as the substrate 101. Alternatively, a single crystal semiconductor substrate or a polycrystalline semiconductor substrate made of silicon or silicon carbide, a compound semiconductor substrate made of silicon germanium, an SOI substrate, or the like can be used as the substrate 101. Still alternatively, any of these substrates provided with a semiconductor element may be used as the substrate 101.

Still alternatively, a flexible substrate such as a plastic substrate may be used as the substrate 101, and the transistor 100 may be provided directly on the flexible substrate. Further alternatively, a separation layer may be provided between the substrate 101 and the transistor 100. The separation layer can be used when part or the whole of the transistor is formed over the separation layer and separated from the substrate 101 and transferred to another substrate. Thus, the transistor 100 can be transferred to a substrate having low heat resistance or a flexible substrate.

### <<Gate Electrode>>

The gate electrode 102 can be formed using a metal selected from aluminum, chromium, copper, tantalum, titanium, molybdenum, and tungsten; an alloy containing any of these metals as a component; an alloy containing any of these metals in combination; or the like. Further, one or more metals selected from manganese and zirconium may be used. Furthermore, the gate electrode 102 may have a single-layer structure or a stacked-layer structure of two or more layers. For example, a single-layer structure of an aluminum film containing silicon, a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, a three-layer structure in which a titanium film, an aluminum film, and a titanium film are stacked in this order, and the like can be given. Alternatively, an alloy film or a nitride film which contains aluminum and one or more selected from titanium, tantalum, tungsten, molybdenum, chromium, neodymium, and scandium film may be used.

The gate electrode 102 can also be formed using a light-transmitting conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added. It is also possible to have a stacked-layer structure formed using the above light-transmitting conductive material and the above metal.

Further, an In—Ga—Zn-based oxynitride semiconductor film, an In—Sn-based oxynitride semiconductor film, an In—Ga-based oxynitride semiconductor film, an In—Zn-based oxynitride semiconductor film, a Sn-based oxynitride semiconductor film, an In-based oxynitride semiconductor film, a film of metal nitride (such as InN or ZnN), or the like may be provided between the gate electrode 102 and the insulating layer 103. These films each have a work function higher than or equal to 5 eV, preferably higher than or equal to 5.5 eV. Thus, the threshold voltage of the transistor can be shifted in the positive direction, and what is called a normally-off switching element can be achieved. For example, in the case of using an In—Ga—Zn-based oxynitride semiconductor film, an In—Ga—Zn-based oxynitride semiconductor film having a higher nitrogen concentration than at least the oxide semiconductor layer 104, specifically, an In—Ga—Zn-based oxynitride semiconductor film having a nitrogen concentration of 7 at. % or higher is used.

### <<Insulating Layer>>

The insulating layer 103 functions as a gate insulating film. The insulating layer 103 in contact with the bottom surface of the oxide semiconductor layer 104 is preferably an oxide insulating film.

The insulating layer 103 may be formed to have a single-layer structure or a stacked-layer structure using, for example, one or more of silicon oxide, silicon oxynitride, silicon nitride oxide, silicon nitride, aluminum oxide, hafnium oxide, gallium oxide, Ga—Zn-based metal oxide, and the like.

The insulating layer 103 may be formed using a high-k material such as hafnium silicate (HfSiOₓ), hafnium silicate to which nitrogen is added (HfSiₓO_{y}N_{z}), hafnium aluminate to which nitrogen is added (HfAlₓO_{y}N_{z}), hafnium oxide, or yttrium oxide, so that gate leakage current of the transistor can be reduced.

### <<Pair of Electrodes>>

The pair of electrodes 105a and 105b function as a source electrode and a drain electrode of the transistor.

The pair of electrodes 105a and 105b can be formed to have a single-layer structure or a stacked-layer structure using, as a conductive material, any of metals such as aluminum, titanium, chromium, nickel, copper, yttrium, zirconium, molybdenum, silver, tantalum, and tungsten, or an alloy containing any of these metals as its main component. For example, a single-layer structure of an aluminum film containing silicon, a two-layer structure in which a titanium film is stacked over an aluminum film, a two-layer structure in which a titanium film is stacked over a tungsten film, a two-layer structure in which a copper film is stacked over a copper-magnesium-aluminum alloy film, a three-layer structure in which a titanium film or a titanium nitride film, an aluminum film or a copper film, and a titanium film or a titanium nitride film are stacked in this order, a three-layer structure in which a molybdenum film or a molybdenum nitride film, an aluminum film or a copper film, and a molybdenum film or a molybdenum nitride film are stacked in this order, and the like can be given. Note that a transparent conductive material containing indium oxide, tin oxide, or zinc oxide may be used.

### <<Insulating Layer>>

The insulating layer 106 is preferably formed using an oxide insulating film containing oxygen at a higher proportion than oxygen in the stoichiometric composition. Part of oxygen is released by heating from the oxide insulating film containing oxygen at a higher proportion than oxygen in the stoichiometric composition. The oxide insulating film containing oxygen at a higher proportion than oxygen in the stoichiometric composition is an oxide insulating film in which the amount of released oxygen converted into oxygen atoms is greater than or equal to 1.0×10¹⁸ atoms/cm³, preferably greater than or equal to 3.0×10²⁰ atoms/cm³ in thermal desorption spectroscopy (TDS) analysis. Note that the temperature of the film surface in the TDS analysis is preferably higher than or equal to 100° C. and lower than or equal to 700° C., or higher than or equal to 100° C. and lower than or equal to 500° C.

As the insulating layer 106, a silicon oxide film, a silicon oxynitride film, or the like can be formed.

Note that the insulating layer 106 also functions as a film which relieves damage to the oxide semiconductor layer 104 at the time of forming the insulating layer 107 later.

Alternatively, an oxide film transmitting oxygen may be provided between the insulating layer 106 and the oxide semiconductor layer 104.

As the oxide film transmitting oxygen, a silicon oxide film, a silicon oxynitride film, or the like can be formed. Note that in this specification, a “silicon oxynitride film” refers to a film that contains oxygen at a higher proportion than nitrogen, and a “silicon nitride oxide film” refers to a film that contains nitrogen at a higher proportion than oxygen.

The insulating layer 107 can be formed using an insulating film having a blocking effect against oxygen, hydrogen, water, and the like. It is possible to prevent outward diffusion of oxygen from the oxide semiconductor layer 104 and entry of hydrogen, water, or the like into the oxide semiconductor layer 104 from the outside by providing the insulating layer 107 over the insulating layer 106. As for the insulating film having a blocking effect against oxygen, hydrogen, water, and the like, a silicon nitride film, a silicon nitride oxide film, an aluminum oxide film, an aluminum oxynitride film, a gallium oxide film, a gallium oxynitride film, an yttrium oxide film, an yttrium oxynitride film, a hafnium oxide film, and a hafnium oxynitride film can be given as examples.

### <Example of Method for Manufacturing Transistor>

Next, an example of a method for manufacturing the transistor 100 illustrated in FIGS. 14A and 14B will be described.

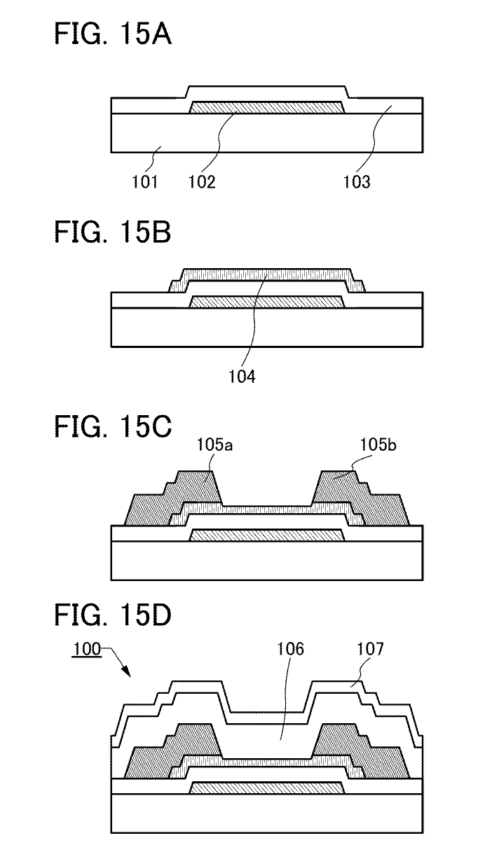

First, as illustrated in FIG. 15A, the gate electrode 102 is formed over the substrate 101, and the insulating layer 103 is formed over the gate electrode 102.

Here, a glass substrate is used as the substrate 101.

### <<Formation of Gate Electrode>>

A formation method of the gate electrode 102 will be described below. First, a conductive film is formed by a sputtering method, a CVD method, an evaporation method, or the like and then a resist mask is formed over the conductive film using a first photomask by a photolithography process. Then, part of the conductive film is etched using the resist mask to form the gate electrode 102. After that, the resist mask is removed.

Note that instead of the above formation method, the gate electrode 102 may be formed by an electrolytic plating method, a printing method, an ink-jet method, or the like.

### <<Formation of Gate Insulating Layer>>

The insulating layer 103 is formed by a sputtering method, a PECVD method, an evaporation method, or the like.

In the case where the insulating layer 103 is formed using a silicon oxide film, a silicon oxynitride film, or a silicon nitride oxide film, a deposition gas containing silicon and an oxidizing gas are preferably used as a source gas. Typical examples of the deposition gas containing silicon include silane, disilane, trisilane, and silane fluoride. As the oxidizing gas, oxygen, ozone, dinitrogen monoxide, and nitrogen dioxide can be given as examples.

In the case of forming a silicon nitride film as the insulating layer 103, it is preferable to use a two-step formation method. First, a first silicon nitride film with a small number of defects is formed by a plasma CVD method in which a mixed gas of silane, nitrogen, and ammonia is used as a source gas. Then, a second silicon nitride film in which the hydrogen concentration is low and hydrogen can be blocked is formed by switching the source gas to a mixed gas of silane and nitrogen. With such a formation method, a silicon nitride film with a small number of defects and a blocking property against hydrogen can be formed as the insulating layer 103.

Moreover, in the case of forming a gallium oxide film as the insulating layer 103, a metal organic chemical vapor deposition (MOCVD) method can be employed.

### <<Formation of Oxide Semiconductor Layer>>

Next, as illustrated in FIG. 15B, the oxide semiconductor layer 104 is formed over the insulating layer 103.

A formation method of the oxide semiconductor layer 104 will be described below. First, an oxide semiconductor film is formed. Then, a resist mask is formed over the oxide semiconductor film using a second photomask by a photolithography process. Then, part of the oxide semiconductor film is etched using the resist mask to form the oxide semiconductor layer 104. After that, the resist mask is removed.

After that, heat treatment may be performed. In such a case, the heat treatment is preferably performed under an atmosphere containing oxygen. The temperature of the heat treatment may be, for example, higher than or equal to 150° C. and lower than or equal to 600° C., preferably higher than or equal to 200° C. and lower than or equal to 500° C.

### <<Formation of Pair of Electrodes>>

Next, as illustrated in FIG. 15C, the pair of electrodes 105a and 105b is formed.

A formation method of the pair of electrodes 105a and 105b will be described below. First, a conductive film is formed by a sputtering method, a PECVD method, an evaporation method, or the like. Then, a resist mask is formed over the conductive film using a third photomask by a photolithography process. Then, part of the conductive film is etched using the resist mask to form the pair of electrodes 105a and 105b. After that, the resist mask is removed.

Note that as illustrated in FIG. 15B, an upper part of the oxide semiconductor layer 104 is in some cases partly etched and thinned by the etching of the conductive film. For this reason, the oxide semiconductor layer 104 is preferably formed thick.

### <<Formation of Insulating Layer>>

Next, as illustrated in FIG. 15D, the insulating layer 106 is formed over the oxide semiconductor layer 104 and the pair of electrodes 105a and 105b, and the insulating layer 107 is successively formed over the insulating layer 106.

In the case where the insulating layer 106 is formed using a silicon oxide film or a silicon oxynitride film, a deposition gas containing silicon and an oxidizing gas are preferably used as a source gas. Typical examples of the deposition gas containing silicon include silane, disilane, trisilane, and silane fluoride. As the oxidizing gas, oxygen, ozone, dinitrogen monoxide, and nitrogen dioxide can be given as examples.

For example, a silicon oxide film or a silicon oxynitride film is formed under the conditions as follows: the substrate placed in a treatment chamber of a plasma CVD apparatus, which is vacuum-evacuated, is held at a temperature higher than or equal to 180° C. and lower than or equal to 260° C., preferably higher than or equal to 200° C. and lower than or equal to 240° C., the pressure is greater than or equal to 100 Pa and less than or equal to 250 Pa, preferably greater than or equal to 100 Pa and less than or equal to 200 Pa with introduction of a source gas into the treatment chamber, and high-frequency power higher than or equal to 0.17 W/cm² and lower than or equal to 0.5 W/cm², preferably higher than or equal to 0.25 W/cm² and lower than or equal to 0.35 W/cm² is supplied to an electrode provided in the treatment chamber.

As the film formation conditions, the high-frequency power having the above power density is supplied to the treatment chamber having the above pressure, whereby the decomposition efficiency of the source gas in plasma is increased, oxygen radicals are increased, and oxidation of the source gas is promoted; therefore, oxygen is contained in the oxide insulating film at a higher proportion than oxygen in the stoichiometric composition. However, in the case where the substrate temperature is within the above temperature range, the bond between silicon and oxygen is weak, and accordingly, part of oxygen is released by heating. Thus, it is possible to form an oxide insulating film which contains oxygen at a higher proportion than oxygen in the stoichiometric composition and from which part of oxygen is released by heating.

Further, in the case of providing an oxide insulating film between the oxide semiconductor layer 104 and the insulating layer 106, the oxide insulating film serves as a protective film for the oxide semiconductor layer 104 in the steps of forming the insulating layer 106. Thus, the insulating layer 106 can be formed using the high-frequency power having a high power density while damage to the oxide semiconductor layer 104 is reduced.

For example, a silicon oxide film or a silicon oxynitride film is formed as the oxide insulating film under the conditions as follows: the substrate placed in a treatment chamber of a PECVD apparatus, which is vacuum-evacuated, is held at a temperature higher than or equal to 180° C. and lower than or equal to 400° C., preferably higher than or equal to 200° C. and lower than or equal to 370° C., the pressure is greater than or equal to 20 Pa and less than or equal to 250 Pa, preferably greater than or equal to 100 Pa and less than or equal to 250 Pa with introduction of a source gas into the treatment chamber, and high-frequency power is supplied to an electrode provided in the treatment chamber. Further, when the pressure in the treatment chamber is greater than or equal to 100 Pa and less than or equal to 250 Pa, damage to the oxide semiconductor layer 104 can be reduced.

A deposition gas containing silicon and an oxidizing gas are preferably used as a source gas of the oxide insulating film. Typical examples of the deposition gas containing silicon include silane, disilane, trisilane, and silane fluoride. As the oxidizing gas, oxygen, ozone, dinitrogen monoxide, and nitrogen dioxide can be given as examples.

The insulating layer 107 can be formed by a sputtering method, a PECVD method, or the like.

In the case where the insulating layer 107 is formed using a silicon nitride film or a silicon nitride oxide film, a deposition gas containing silicon, an oxidizing gas, and a gas containing nitrogen are preferably used as a source gas. Typical examples of the deposition gas containing silicon include silane, disilane, trisilane, and silane fluoride. As the oxidizing gas, oxygen, ozone, dinitrogen monoxide, and nitrogen dioxide can be given as examples. As the gas containing nitrogen, nitrogen and ammonia can be given as examples.

Through the above process, the transistor 100 can be formed.

### <Modification Example of Transistor>

A structural example of a transistor, which is partly different from the transistor 100, will be described below.

### Modification Example 1

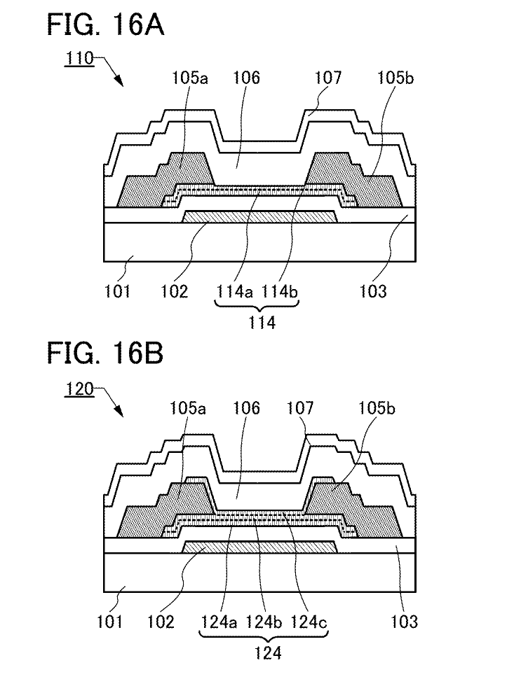

FIG. 16A is a schematic cross-sectional view of a transistor 110 described as an example below. The transistor 110 is different from the transistor 100 in the structure of an oxide semiconductor layer.

In an oxide semiconductor layer 114 included in the transistor 110, an oxide semiconductor layer 114a and an oxide semiconductor layer 114b are stacked.

Since a boundary between the oxide semiconductor layer 114a and the oxide semiconductor layer 114b is unclear in some cases, the boundary is shown by a dashed line in FIG. 16A and the like.

Typical examples of a material that can be used for the oxide semiconductor layer 114a are an In—Ga oxide, an In—Zn oxide, and an In-M-Zn oxide (M is Al, Ti, Ga, Y, Zr, La, Ce, Nd, or Hf). When an In-M-Zn oxide is used for the oxide semiconductor layer 114a, the atomic ratio of In and M, not taking Zn and O into consideration, is preferably as follows: the atomic percentage of In is less than 50 at. % and the atomic percentage of M is greater than or equal to 50 at. %; further preferably, the atomic percentage of In is less than 25 at. % and the atomic percentage of M is greater than or equal to 75 at. %. Further, a material having an energy gap of 2 eV or more, preferably 2.5 eV or more, further preferably 3 eV or more is used for the oxide semiconductor layer 114a, for example.

The oxide semiconductor layer 114b contains In or Ga; the oxide semiconductor layer 114b contains, for example, a material typified by an In—Ga oxide, an In—Zn oxide, or an In-M-Zn oxide (M is Al, Ti, Ga, Y, Zr, La, Ce, Nd, or Hf). In addition, the energy of the conduction band minimum of the oxide semiconductor layer 114b is closer to the vacuum level than that of the oxide semiconductor layer 114a is. The difference between the energy of the conduction band minimum of the oxide semiconductor layer 114b and the energy of the conduction band minimum of the oxide semiconductor layer 114a is preferably 0.05 eV or more, 0.07 eV or more, 0.1 eV or more, or 0.15 eV or more and 2 eV or less, 1 eV or less, 0.5 eV or less, or 0.4 eV or less.

When an In-M-Zn oxide is used for the oxide semiconductor layer 114b, for example, the atomic ratio of In and M, not taking Zn and O into consideration, is preferably as follows: the atomic percentage of In is greater than or equal to 25 at. % and the atomic percentage of M is less than 75 at. %; further preferably, the atomic percentage of In is greater than or equal to 34 at. % and the atomic percentage of M is less than 66 at. %.

For the oxide semiconductor layer 114a, an In—Ga—Zn oxide containing In, Ga, and Zn at an atomic ratio of 1:1:1, 1:1:1.2, or 3:1:2 can be used, for example. Further, for the oxide semiconductor layer 114b, an In—Ga—Zn oxide containing In, Ga, and Zn at an atomic ratio of 1:3:2, 1:6:4, or 1:9:6 can be used. Note that the atomic ratio of each of the oxide semiconductor layers 114a and 114b varies within a range of ±20% of the above atomic ratio as an error.

When an oxide containing a large amount of Ga that serves as a stabilizer is used for the oxide semiconductor layer 114b provided over the oxide semiconductor layer 114a, oxygen can be prevented from being released from the oxide semiconductor layers 114a and 114b.

Note that, without limitation to those described above, a material with an appropriate composition may be used depending on required semiconductor characteristics and electrical characteristics (e.g., field-effect mobility and threshold voltage) of a transistor. Further, in order to obtain required semiconductor characteristics of a transistor, it is preferable that the carrier density, the impurity concentration, the defect density, the atomic ratio of a metal element to oxygen, the interatomic distance, the density, and the like of the oxide semiconductor layers 114a and 114b be set to be appropriate.

Although a structure in which two oxide semiconductor layers are stacked is described above as an example of the oxide semiconductor layer 114, a structure in which three or more oxide semiconductor layers are stacked can also be employed.

### Modification Example 2

FIG. 16B is a schematic cross-sectional view of a transistor 120 described as an example below. The transistor 120 is different from the transistor 100 and the transistor 110 in the structure of an oxide semiconductor layer.

In an oxide semiconductor layer 124 included in the transistor 120, an oxide semiconductor layer 124a, an oxide semiconductor layer 124b, and an oxide semiconductor layer 124c are stacked in this order.

The oxide semiconductor layers 124a and 124b are stacked over the insulating layer 103. The oxide semiconductor layer 124c is provided in contact with the top surface of the oxide semiconductor layer 124b and the top surfaces and side surfaces of the pair of electrodes 105a and 105b.

The oxide semiconductor layer 124b can have a structure which is similar to that of the oxide semiconductor layer 114a described as an example in Modification Example 1, for example. Further, the oxide semiconductor layers 124a and 124c can each have a structure which is similar to that of the oxide semiconductor layer 114b described as an example in Modification Example 1, for example.

When an oxide containing a large amount of Ga that serves as a stabilizer is used for the oxide semiconductor layer 124a, which is provided under the oxide semiconductor layer 124b, and the oxide semiconductor layer 124c, which is provided over the oxide semiconductor layer 124b, for example, oxygen can be prevented from being released from the oxide semiconductor layer 124a, the oxide semiconductor layer 124b, and the oxide semiconductor layer 124c.

In the case where a channel is mainly formed in the oxide semiconductor layer 124b, for example, an oxide containing a large amount of In can be used for the oxide semiconductor layer 124b and the pair of electrodes 105a and 105b is provided in contact with the oxide semiconductor layer 124b; thus, the on-state current of the transistor 120 can be increased.

### <Another Structural Example of Transistor>

A structural example of a top-gate transistor to which the oxide semiconductor film of one embodiment of the present invention can be applied will be described below.

Note that descriptions of components having structures or functions similar to those of the above, which are denoted by the same reference numerals, are omitted below.

### <<Structural Example>>

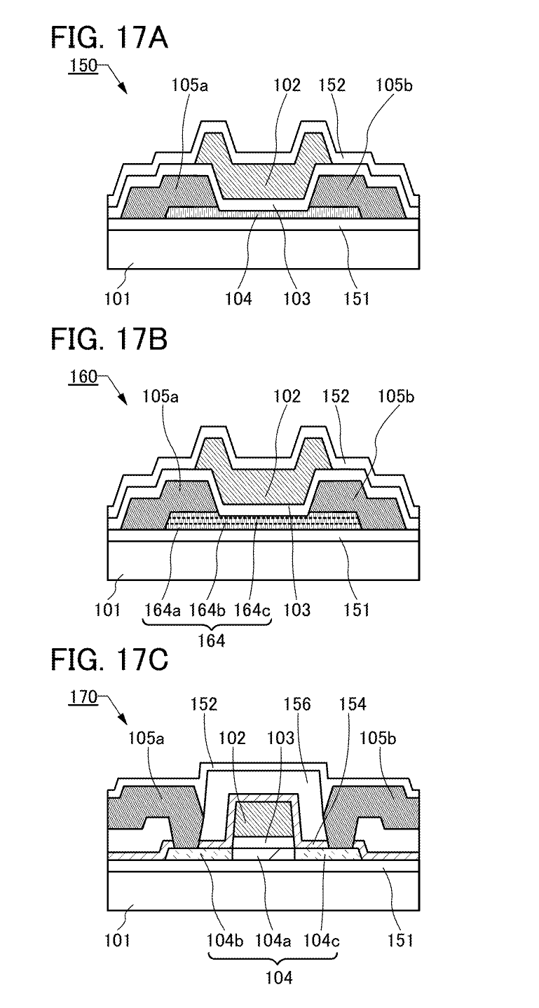

FIG. 17A is a schematic cross-sectional view of a top-gate transistor 150 which will be described below as an example.

The transistor 150 includes the oxide semiconductor layer 104 over the substrate 101 on which an insulating layer 151 is provided, the pair of electrodes 105a and 105b in contact with the top surface of the oxide semiconductor layer 104, the insulating layer 103 over the oxide semiconductor layer 104 and the pair of electrodes 105a and 105b, and the gate electrode 102 provided over the insulating layer 103 so as to overlap with the oxide semiconductor layer 104. Further, an insulating layer 152 is provided to cover the insulating layer 103 and the gate electrode 102.

The insulating layer 151 has a function of suppressing diffusion of impurities from the substrate 101 into the oxide semiconductor layer 104. For example, a structure similar to that of the insulating layer 107 can be employed. Note that the insulating layer 151 is not necessarily provided.

The insulating layer 152 can be formed using an insulating film having a blocking effect against oxygen, hydrogen, water, and the like in a manner similar to that of the insulating layer 107. Note that the insulating layer 107 need not necessarily be provided.

### Modification Example 1

A structural example of a transistor, which is partly different from the transistor 150, will be described below.

FIG. 17B is a schematic cross-sectional view of a transistor 160 described as an example below. The structure of an oxide semiconductor layer in the transistor 160 is different from that in the transistor 150.

In an oxide semiconductor layer 164 included in the transistor 160, an oxide semiconductor layer 164a, an oxide semiconductor layer 164b, and an oxide semiconductor layer 164c are stacked in this order.

The above-described oxide semiconductor film can be applied to one or more of the oxide semiconductor layer 164a, the oxide semiconductor layer 164b, and the oxide semiconductor layer 164c.

The oxide semiconductor layer 164b can have a structure which is similar to that of the oxide semiconductor layer 114a described as an example in Modification example 1, for example. Further, the oxide semiconductor layers 164a and 164c can each have a structure which is similar to that of the oxide semiconductor layer 114b described as an example in Modification example 1, for example.

An oxide containing a large amount of Ga that serves as a stabilizer is used for the oxide semiconductor layer 164a, which is provided under the oxide semiconductor layer 164b, and the oxide semiconductor layer 164c, which is provided over the oxide semiconductor layer 164b; thus, oxygen can be prevented from being released from the oxide semiconductor layer 164a, the oxide semiconductor layer 164b, and the oxide semiconductor layer 164c.

### Modification Example 2

A structural example of a transistor, which is partly different from the transistor 150, will be described below.

FIG. 17C is a schematic cross-sectional view of a transistor 170 described below as an example. The transistor 170 is different from the transistor 150 in the shapes of the pair of electrodes 105a and 105b in contact with the oxide semiconductor layer 104, the shape of the gate electrode 102, and the like.

The transistor 170 includes the oxide semiconductor layer 104 provided over the substrate 101 provided with the insulating layer 151, the insulating layer 103 over the oxide semiconductor layer 104, the gate electrode 102 over the insulating layer 103, an insulating layer 154 over the insulating layer 151 and the oxide semiconductor layer 104, an insulating layer 156 over the insulating layer 154, the pair of electrodes 105a and 105b electrically connected to the oxide semiconductor layer 104 through openings provided in the insulating layers 154 and 156, and the insulating layer 152 over the insulating layer 156 and the pair of electrodes 105a and 105b.

The insulating layer 154 is formed with, for example, an insulating film including hydrogen. An example of the insulating film including hydrogen is a silicon nitride film. Hydrogen included in the insulating layer 154 becomes a carrier in the oxide semiconductor layer 104 when bonded to an oxygen vacancy in the oxide semiconductor layer 104. Thus, in the structure illustrated in FIG. 17C, regions of the oxide semiconductor layer 104 in contact with the insulating layer 154 are expressed as an n-type region 104b and an n-type region 104c. Note that a region sandwiched between the n-type region 104b and the n-type region 104c is a channel region 104a.

By forming the n-type regions 104b and 104c in the oxide semiconductor layer 104, the contact resistance with the pair of electrodes 105a and 105b can be reduced. Note that the n-type regions 104b and 104c can be formed in a self-aligned manner during the formation of the gate electrode 102, using the insulating layer 154 that covers the gate electrode 102. The transistor 170 illustrated in FIG. 17C is what is called a self-aligned top gate transistor. In the self-aligned top gate transistor, the gate electrode 102 and the pair of electrodes 105a and 105b which function as a source electrode and a drain electrode do not overlap, which can reduce the parasitic capacitance generated between the electrodes.

The insulating layer 156 included in the transistor 170 can be formed with, for example, a silicon oxynitride film.

This embodiment can be combined with any of the other embodiments disclosed in this specification as appropriate.

### Embodiment 6

In this embodiment, the structure of an oxide semiconductor that can be used in a display module of one embodiment of the present invention will be described.

An oxide semiconductor forming the oxide film has a wide energy gap of 3.0 eV or more. A transistor including an oxide semiconductor film obtained by processing of the oxide semiconductor in an appropriate condition and a sufficient reduction in carrier density of the oxide semiconductor can have much lower off-state current than a conventional transistor including silicon.

An applicable oxide semiconductor preferably contains at least indium (In) or zinc (Zn). In particular, In and Zn are preferably contained. In addition, as a stabilizer for reducing variation in electrical characteristics of the transistor using the oxide semiconductor, one or more selected from gallium (Ga), tin (Sn), hafnium (Hf), zirconium (Zr), titanium (Ti), scandium (Sc), yttrium (Y), and an lanthanoid (e.g., cerium (Ce), neodymium (Nd), or gadolinium (Gd)) is preferably contained.

As the oxide semiconductor, for example, any of the following can be used: indium oxide, tin oxide, zinc oxide, an In—Zn-based oxide, a Sn—Zn-based oxide, an Al—Zn-based oxide, a Zn—Mg-based oxide, a Sn—Mg-based oxide, an In—Mg-based oxide, an In—Ga-based oxide, an In—Ga—Zn-based oxide (also referred to as IGZO), an In—Al—Zn-based oxide, an In—Sn—Zn-based oxide, a Sn—Ga—Zn-based oxide, an Al—Ga—Zn-based oxide, a Sn—Al—Zn-based oxide, an In—Hf—Zn-based oxide, an In—Zr—Zn-based oxide, an In—Ti—Zn-based oxide, an In—Sc—Zn-based oxide, an In—Y—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, an In—Lu—Zn-based oxide, an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, or an In—Hf—Al—Zn-based oxide.

Here, an “In—Ga—Zn-based oxide” means an oxide containing In, Ga, and Zn as its main components and there is no particular limitation on the ratio of In:Ga:Zn. The In—Ga—Zn-based oxide may contain a metal element other than the In, Ga, and Zn.

Alternatively, a material represented by InMO₃(ZnO)ₘ (m>0 is satisfied, and m is not an integer) may be used as an oxide semiconductor. Note that M represents one or more metal elements selected from Ga, Fe, Mn, and Co, or the above-described element as a stabilizer. Alternatively, as the oxide semiconductor, a material expressed by a chemical formula, In₂SnO₅(ZnO)ₙ (n>0, n is an integer) may be used.

For example, In—Ga—Zn-based oxide with an atomic ratio of In:Ga:Zn=1:1:1, 1:3:2, 1:3:4, 1:3:6, 3:1:2, or 2:1:3, or an oxide whose composition is in the neighborhood of the above compositions may be used.

Note that if the oxide semiconductor film contains a large amount of hydrogen, the hydrogen and the oxide semiconductor are bonded to each other, so that part of the hydrogen serves as a donor and causes generation of an electron that is a carrier. As a result, the threshold voltage of the transistor shifts in the negative direction. Therefore, it is preferable that, after formation of the oxide semiconductor film, dehydration treatment (dehydrogenation treatment) be performed to remove hydrogen or moisture from the oxide semiconductor film so that the oxide semiconductor film is highly purified to contain impurities as little as possible.

Note that oxygen in the oxide semiconductor film is also reduced by the dehydration treatment (dehydrogenation treatment) in some cases. Therefore, it is preferable that oxygen be added to the oxide semiconductor film to fill oxygen vacancies increased by the dehydration treatment (dehydrogenation treatment). In this specification and the like, supplying oxygen to an oxide semiconductor film may be expressed as oxygen adding treatment, or treatment for making the oxygen content of an oxide semiconductor film be in excess of that of the stoichiometric composition may be expressed as treatment for making an oxygen-excess state.

In this manner, hydrogen or moisture is removed from the oxide semiconductor film by the dehydration treatment (dehydrogenation treatment) and oxygen vacancies therein are filled by the oxygen adding treatment, so that the oxide semiconductor film can be an i-type (intrinsic) oxide semiconductor film or an oxide semiconductor film extremely close to an i-type oxide semiconductor (a substantially i-type oxide semiconductor). Note that “substantially intrinsic” refers to the state where an oxide semiconductor layer has a carrier density which is lower than 1×10¹⁷/cm³, preferably lower than 1×10¹⁵/cm³, more preferably lower than 1×10¹³/cm³, further preferably lower than 8×10¹¹/cm³, still further preferably lower than 1×10¹¹/cm³, yet further preferably lower than 1×10¹⁰/cm³, and is 1×10⁻⁹/cm³ or higher.

In this manner, the transistor including an i-type or substantially i-type oxide semiconductor film can have extremely favorable off-state current characteristics. For example, the drain current at the time when the transistor including an oxide semiconductor film is in an off-state at room temperature (25° C.) can be less than or equal to 1×10⁻¹⁸ A, preferably less than or equal to 1×10⁻²¹ A, further preferably less than or equal to 1×10⁻²⁴ A; or at 85° C., less than or equal to 1×10⁻¹⁵ A, preferably less than or equal to 1×10⁻¹⁸ A, further preferably less than or equal to 1×10⁻²¹ A. An off state of a transistor refers to a state where gate voltage is lower than the threshold voltage in an n-channel transistor. Specifically, the transistor is in an off state when the gate voltage is lower than the threshold voltage by 1V or more, 2V or more, or 3V or more.

A structure of the oxide semiconductor film will be described below.

In this specification, the term “parallel” indicates that the angle formed between two straight lines is greater than or equal to −10° and less than or equal to 10°, and accordingly also includes the case where the angle is greater than or equal to −5° and less than or equal to 5°. The term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°, and accordingly includes the case where the angle is greater than or equal to 85° and less than or equal to 95°. The term “substantially perpendicular” indicates that the angle formed between two straight lines is greater than or equal to 60° and less than or equal to 120°.

In this specification, trigonal and rhombohedral crystal systems are included in a hexagonal crystal system.

An oxide semiconductor is classified into a single crystal oxide semiconductor and a non-single-crystal oxide semiconductor. Examples of a non-single-crystal oxide semiconductor include a c-axis aligned crystalline oxide semiconductor (CAAC-OS), a polycrystalline oxide semiconductor, a microcrystalline oxide semiconductor, and an amorphous oxide semiconductor.

From another perspective, an oxide semiconductor is classified into an amorphous oxide semiconductor and a crystalline oxide semiconductor. Examples of a crystalline oxide semiconductor include a single crystal oxide semiconductor, a CAAC-OS, a polycrystalline oxide semiconductor, and a microcrystalline oxide semiconductor.

First, a CAAC-OS will be described. Note that a CAAC-OS can be referred to as an oxide semiconductor including c-axis aligned nanocrystals (CANC).

A CAAC-OS is one of oxide semiconductors having a plurality of c-axis aligned crystal parts (also referred to as pellets).

In a combined analysis image (also referred to as a high-resolution TEM image) of a bright-field image and a diffraction pattern of a CAAC-OS, which is obtained using a transmission electron microscope (TEM), a plurality of pellets can be observed. However, in the high-resolution TEM image, a boundary between pellets, that is, a grain boundary is not clearly observed. Thus, in the CAAC-OS, a reduction in electron mobility due to the grain boundary is less likely to occur.

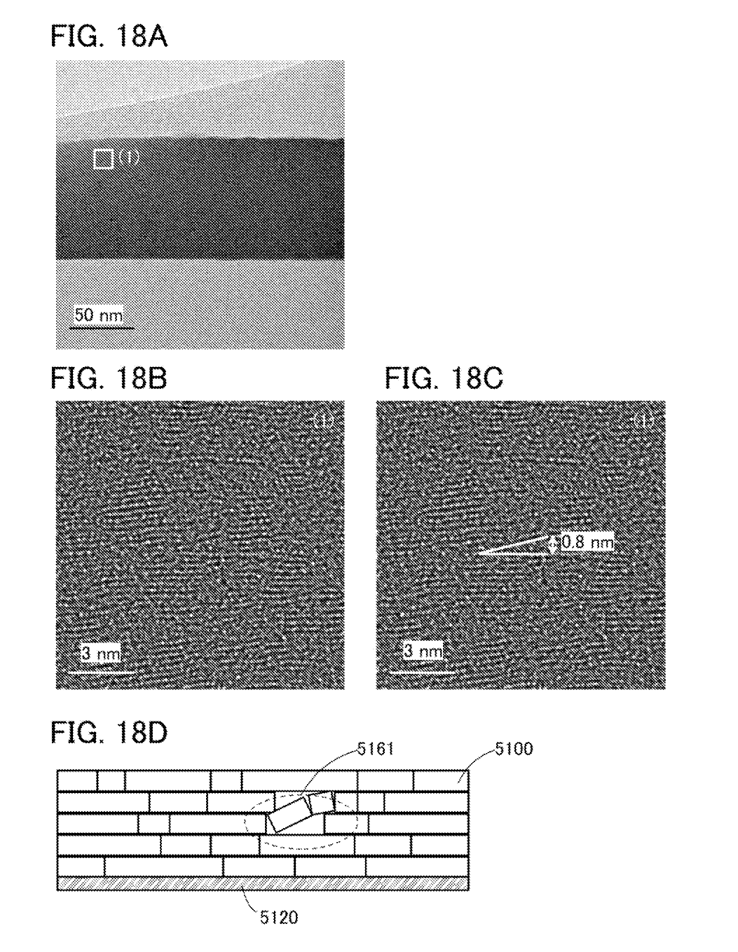

A CAAC-OS observed with TEM will be described below. FIG. 18A shows a high-resolution TEM image of a cross section of the CAAC-OS which is observed from a direction substantially parallel to the sample surface. The high-resolution TEM image is obtained with a spherical aberration corrector function. The high-resolution TEM image obtained with a spherical aberration corrector function is particularly referred to as a Cs-corrected high-resolution TEM image. The Cs-corrected high-resolution TEM image can be obtained with, for example, an atomic resolution analytical electron microscope JEM-ARM200F manufactured by JEOL Ltd.

FIG. 18B is an enlarged Cs-corrected high-resolution TEM image of a region (1) in FIG. 18A. FIG. 18B shows that metal atoms are arranged in a layered manner in a pellet. Each metal atom layer has a configuration reflecting unevenness of a surface over which the CAAC-OS is formed (hereinafter, the surface is referred to as a formation surface) or a top surface of the CAAC-OS, and is arranged parallel to the formation surface or the top surface of the CAAC-OS.

As shown in FIG. 18B, the CAAC-OS has a characteristic atomic arrangement. The characteristic atomic arrangement is denoted by an auxiliary line in FIG. 18C. FIGS. 18B and 18C prove that the size of a pellet is approximately 1 nm to 3 nm, and the size of a space caused by tilt of the pellets is approximately 0.8 nm. Therefore, the pellet can also be referred to as a nanocrystal (nc).

Here, according to the Cs-corrected high-resolution TEM images, the schematic arrangement of pellets 5100 of a CAAC-OS over a substrate 5120 is illustrated by such a structure in which bricks or blocks are stacked (see FIG. 18D). The part in which the pellets are tilted as observed in FIG. 18C corresponds to a region 5161 shown in FIG. 18D.

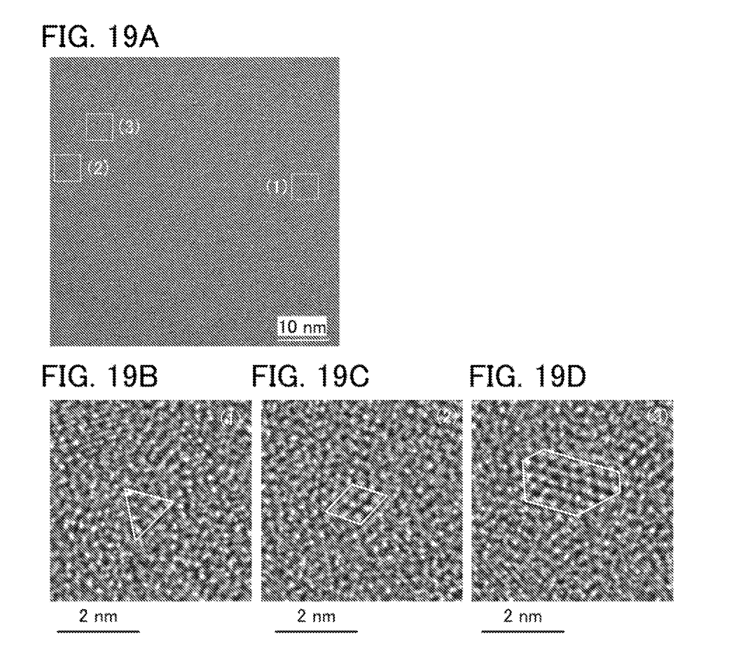

FIG. 19A shows a Cs-corrected high-resolution TEM image of a plane of the CAAC-OS observed from a direction substantially perpendicular to the sample surface. FIGS. 19B, 19C, and 19D are enlarged Cs-corrected high-resolution TEM images of regions (1), (2), and (3) in FIG. 19A, respectively. FIGS. 19B, 19C, and 19D indicate that metal atoms are arranged in a triangular, quadrangular, or hexagonal configuration in a pellet. However, there is no regularity of arrangement of metal atoms between different pellets.

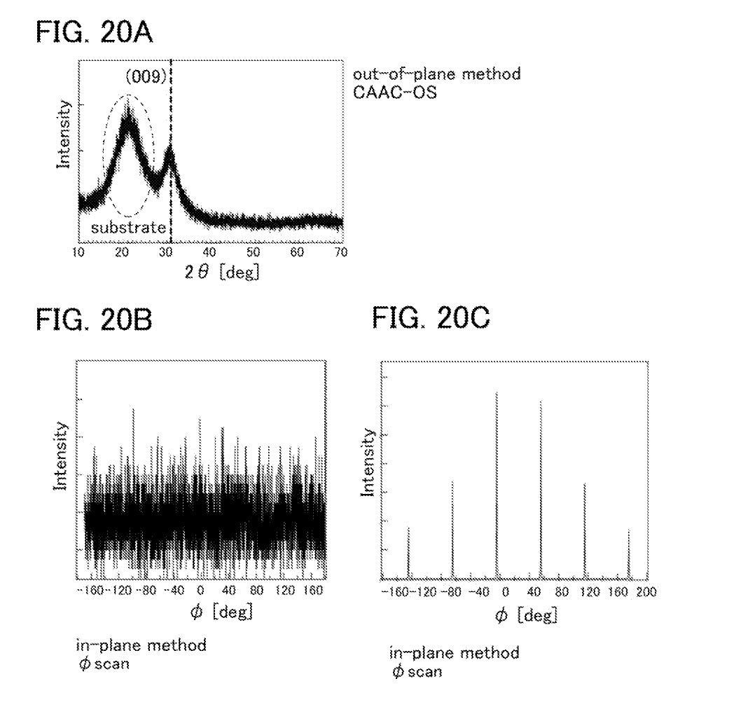

Next, a CAAC-OS analyzed by X-ray diffraction (XRD) will be described. For example, when the structure of a CAAC-OS including an InGaZnO₄ crystal is analyzed by an out-of-plane method, a peak appears at a diffraction angle (2θ) of around 31° as shown in FIG. 20A. This peak is derived from the (009) plane of the InGaZnO₄ crystal, which indicates that crystals in the CAAC-OS have c-axis alignment, and that the c-axes are aligned in a direction substantially perpendicular to the formation surface or the top surface of the CAAC-OS.

Note that in structural analysis of the CAAC-OS by an out-of-plane method, another peak may appear when 2θ is around 36°, in addition to the peak at 2θ of around 31°. The peak at 2θ of around 36° indicates that a crystal having no c-axis alignment is included in part of the CAAC-OS. It is preferable that in the CAAC-OS analyzed by an out-of-plane method, a peak appear when 2θ is around 31° and that a peak not appear when 2θ is around 36°.

On the other hand, in structural analysis of the CAAC-OS by an in-plane method in which an X-ray is incident on a sample in a direction substantially perpendicular to the c-axis, a peak appears when 2θ is around 56°. This peak is attributed to the (110) plane of the InGaZnO₄ crystal. In the case of the CAAC-OS, when analysis (φ scan) is performed with 2θ fixed at around 56° and with the sample rotated using a normal vector of the sample surface as an axis (φ axis), as shown in FIG. 20B, a peak is not clearly observed. In contrast, in the case of a single crystal oxide semiconductor of InGaZnO₄, when φ scan is performed with 2θ fixed at around 56°, as shown in FIG. 20C, six peaks which are derived from crystal planes equivalent to the (110) plane are observed. Accordingly, the structural analysis using XRD shows that the directions of a-axes and b-axes are irregularly oriented in the CAAC-OS.

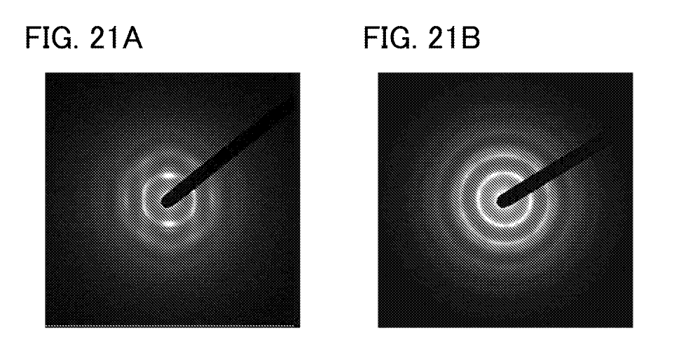

Next, a CAAC-OS analyzed by electron diffraction will be described. For example, when an electron beam with a probe diameter of 300 nm is incident on a CAAC-OS including an InGaZnO₄ crystal in a direction parallel to the sample surface, a diffraction pattern (also referred to as a selected-area transmission electron diffraction pattern) shown in FIG. 21A can be obtained. In this diffraction pattern, spots derived from the (009) plane of an InGaZnO₄ crystal are included. Thus, the electron diffraction also indicates that pellets included in the CAAC-OS have c-axis alignment and that the c-axes are aligned in a direction substantially perpendicular to the formation surface or the top surface of the CAAC-OS. Meanwhile, FIG. 21B shows a diffraction pattern obtained in such a manner that an electron beam with a probe diameter of 300 nm is incident on the same sample in a direction perpendicular to the sample surface. As shown in FIG. 21B, a ring-like diffraction pattern is observed. Thus, the electron diffraction also indicates that the a-axes and b-axes of the pellets included in the CAAC-OS do not have regular alignment. The first ring in FIG. 21B is considered to be derived from the (010) plane, the (100) plane, and the like of the InGaZnO₄ crystal. The second ring in FIG. 21B is considered to be derived from the (110) plane and the like.

Moreover, the CAAC-OS is an oxide semiconductor having a low density of defect states. Defects in the oxide semiconductor are, for example, a defect due to impurity and oxygen vacancies. Therefore, the CAAC-OS can be regarded as an oxide semiconductor with a low impurity concentration, or an oxide semiconductor having a small number of oxygen vacancies.

The impurity contained in the oxide semiconductor might serve as a carrier trap or serve as a carrier generation source. Furthermore, oxygen vacancies in the oxide semiconductor serve as carrier traps or serve as carrier generation sources when hydrogen is captured therein.

Note that the impurity means an element other than the main components of the oxide semiconductor, such as hydrogen, carbon, silicon, or a transition metal element. For example, an element (specifically, silicon or the like) having higher strength of bonding to oxygen than a metal element included in an oxide semiconductor extracts oxygen from the oxide semiconductor, which results in disorder of the atomic arrangement and reduced crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity.

An oxide semiconductor having a low density of defect states (a small number of oxygen vacancies) can have a low carrier density. Such an oxide semiconductor is referred to as a highly purified intrinsic or substantially highly purified intrinsic oxide semiconductor. A CAAC-OS has a low impurity concentration and a low density of defect states. That is, a CAAC-OS is likely to be a highly purified intrinsic or substantially highly purified intrinsic oxide semiconductor. Thus, a transistor including a CAAC-OS rarely has negative threshold voltage (is rarely normally on). The highly purified intrinsic or substantially highly purified intrinsic oxide semiconductor has few carrier traps. An electric charge trapped by the carrier traps in the oxide semiconductor takes a long time to be released. The trapped electric charge may behave like a fixed electric charge. Thus, the transistor which includes the oxide semiconductor having a high impurity concentration and a high density of defect states might have unstable electrical characteristics. However, a transistor including a CAAC-OS has small variation in electrical characteristics and high reliability.

Since the CAAC-OS has a low density of defect states, carriers generated by light irradiation or the like are less likely to be trapped in defect states. Therefore, in a transistor using the CAAC-OS, change in electrical characteristics due to irradiation with visible light or ultraviolet light is small.

Next, a microcrystalline oxide semiconductor will be described.

A microcrystalline oxide semiconductor has a region in which a crystal part is observed and a region in which a crystal part is not clearly observed in a high-resolution TEM image. In most cases, the size of a crystal part included in the microcrystalline oxide semiconductor is greater than or equal to 1 nm and less than or equal to 100 nm, or greater than or equal to 1 nm and less than or equal to 10 nm. An oxide semiconductor including a nanocrystal (nc) that is a microcrystal with a size greater than or equal to 1 nm and less than or equal to 10 nm, or a size greater than or equal to 1 nm and less than or equal to 3 nm is specifically referred to as a nanocrystalline oxide semiconductor (nc-OS). In a high-resolution TEM image of the nc-OS, for example, a grain boundary is not clearly observed in some cases. Note that there is a possibility that the origin of the nanocrystal is the same as that of a pellet in a CAAC-OS. Therefore, a crystal part of the nc-OS may be referred to as a pellet in the following description.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different pellets in the nc-OS. Thus, the orientation of the whole film is not ordered. Accordingly, the nc-OS cannot be distinguished from an amorphous oxide semiconductor, depending on an analysis method. For example, when the nc-OS is subjected to structural analysis by an out-of-plane method with an XRD apparatus using an X-ray having a diameter larger than the size of a pellet, a peak which shows a crystal plane does not appear. Furthermore, a diffraction pattern like a halo pattern is observed when the nc-OS is subjected to electron diffraction using an electron beam with a probe diameter (e.g., 50 nm or larger) that is larger than the size of a pellet (the electron diffraction is also referred to as selected-area electron diffraction). Meanwhile, spots appear in a nanobeam electron diffraction pattern of the nc-OS when an electron beam having a probe diameter close to or smaller than the size of a pellet is applied. Moreover, in a nanobeam electron diffraction pattern of the nc-OS, regions with high luminance in a circular (ring) pattern are shown in some cases. Also in a nanobeam electron diffraction pattern of the nc-OS, a plurality of spots is shown in a ring-like region in some cases.

Since there is no regularity of crystal orientation between the pellets (nanocrystals) as mentioned above, the nc-OS can also be referred to as an oxide semiconductor including random aligned nanocrystals (RANC) or an oxide semiconductor including non-aligned nanocrystals (NANC).

The nc-OS is an oxide semiconductor that has high regularity as compared with an amorphous oxide semiconductor. Therefore, the nc-OS is likely to have a lower density of defect states than an amorphous oxide semiconductor. Note that there is no regularity of crystal orientation between different pellets in the nc-OS. Therefore, the nc-OS has a higher density of defect states than the CAAC-OS.

Next, an amorphous oxide semiconductor will be described.

The amorphous oxide semiconductor is an oxide semiconductor having disordered atomic arrangement and no crystal part and exemplified by an oxide semiconductor which exists in an amorphous state as quartz.

In a high-resolution TEM image of the amorphous oxide semiconductor, crystal parts cannot be found.

When the amorphous oxide semiconductor is subjected to structural analysis by an out-of-plane method with an XRD apparatus, a peak which shows a crystal plane does not appear. A halo pattern is observed when the amorphous oxide semiconductor is subjected to electron diffraction. Furthermore, a spot is not observed and only a halo pattern appears when the amorphous oxide semiconductor is subjected to nanobeam electron diffraction.

There are various understandings of an amorphous structure. For example, a structure whose atomic arrangement does not have ordering at all is called a completely amorphous structure. Meanwhile, a structure which does not have long-range ordering but might have ordering within the range from an atom to the nearest neighbor atom or the second-nearest neighbor atom is called an amorphous structure in some cases. Therefore, the strictest definition does not permit an oxide semiconductor to be called an amorphous oxide semiconductor as long as even a negligible degree of ordering is present in an atomic arrangement. At least an oxide semiconductor having long-term ordering cannot be called an amorphous oxide semiconductor. Accordingly, because of the presence of crystal part, for example, a CAAC-OS and an nc-OS cannot be called an amorphous oxide semiconductor or a completely amorphous oxide semiconductor.

Note that an oxide semiconductor may have a structure between the nc-OS and the amorphous oxide semiconductor. The oxide semiconductor having such a structure is specifically referred to as an amorphous-like oxide semiconductor (a-like OS).

In a high-resolution TEM image of the a-like OS, a void may be observed. Furthermore, in the high-resolution TEM image, there are a region where a crystal part is clearly observed and a region where a crystal part is not observed.

The a-like OS has an unstable structure because it contains a void. To verify that an a-like OS has an unstable structure as compared with a CAAC-OS and an nc-OS, a change in structure caused by electron irradiation will be described below.

An a-like OS (referred to as sample A), an nc-OS (referred to as sample B), and a CAAC-OS (referred to as sample C) are prepared as samples subjected to electron irradiation. Each of the samples is an In—Ga—Zn oxide.

First, a high-resolution cross-sectional TEM image of each sample is obtained. The high-resolution cross-sectional TEM images show that all the samples have crystal parts.

Note that which part is regarded as a crystal part is determined as follows. It is known that a unit cell of an InGaZnO₄ crystal has a structure in which nine layers including three In—O layers and six Ga—Zn—O layers are stacked in the c-axis direction. The distance between the adjacent layers is equivalent to the lattice spacing on the (009) plane (also referred to as d value). The value is calculated to be 0.29 nm from crystal structural analysis. Accordingly, a portion where the lattice spacing between lattice fringes is greater than or equal to 0.28 nm and less than or equal to 0.30 nm is regarded as a crystal part of InGaZnO₄. Each of lattice fringes corresponds to the a-b plane of the InGaZnO₄ crystal.

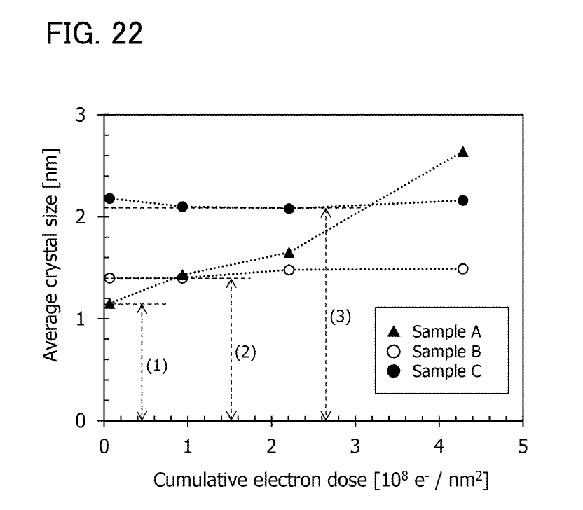

FIG. 22 shows change in the average size of crystal parts (at 22 points to 45 points) in each sample. Note that the crystal part size corresponds to the length of a lattice fringe. FIG. 22 indicates that the crystal part size in the a-like OS increases with an increase in the cumulative electron dose. Specifically, as shown by (1) in FIG. 22, a crystal part of approximately 1.2 nm (also referred to as an initial nucleus) at the start of TEM observation grows to a size of approximately 2.6 nm at a cumulative electron dose of 4.2×10⁸ e⁻/nm². In contrast, the crystal part size in the nc-OS and the CAAC-OS shows little change from the start of electron irradiation to a cumulative electron dose of 4.2×10⁸ e⁻/nm². Specifically, as shown by (2) and (3) in FIG. 22, the average crystal sizes in an nc-OS and a CAAC-OS are approximately 1.4 nm and approximately 2.1 nm, respectively, regardless of the cumulative electron dose.

In this manner, growth of the crystal part in the a-like OS is induced by electron irradiation. In contrast, in the nc-OS and the CAAC-OS, growth of the crystal part is hardly induced by electron irradiation. Therefore, the a-like OS has an unstable structure as compared with the nc-OS and the CAAC-OS.

The a-like OS has a lower density than the nc-OS and the CAAC-OS because it contains a void. Specifically, the density of the a-like OS is higher than or equal to 78.6% and lower than 92.3% of the density of the single crystal oxide semiconductor having the same composition. The density of each of the nc-OS and the CAAC-OS is higher than or equal to 92.3% and lower than 100% of the density of the single crystal oxide semiconductor having the same composition. Note that it is difficult to deposit an oxide semiconductor having a density of lower than 78% of the density of the single crystal oxide semiconductor.

For example, in the case of an oxide semiconductor having an atomic ratio of In:Ga:Zn=1:1:1, the density of single crystal InGaZnO₄ with a rhombohedral crystal structure is 6.357 g/cm³. Accordingly, in the case of the oxide semiconductor having an atomic ratio of In:Ga:Zn=1:1:1, the density of the a-like OS is higher than or equal to 5.0 g/cm³ and lower than 5.9 g/cm³. For example, in the case of the oxide semiconductor having an atomic ratio of In:Ga:Zn=1:1:1, the density of each of the nc-OS and the CAAC-OS is higher than or equal to 5.9 g/cm³ and lower than 6.3 g/cm³.

Note that there is a possibility that an oxide semiconductor having a certain composition cannot exist in a single crystal structure. In that case, single crystal oxide semiconductors with different compositions are combined at an adequate ratio, which makes it possible to calculate density equivalent to that of a single crystal oxide semiconductor with the desired composition. The density of a single crystal oxide semiconductor having the desired composition can be calculated using a weighted average according to the combination ratio of the single crystal oxide semiconductors with different compositions. Note that it is preferable to use as few kinds of single crystal oxide semiconductors as possible to calculate the density.

As described above, oxide semiconductors have various structures and various properties. Note that an oxide semiconductor may be a stacked layer including two or more films of an amorphous oxide semiconductor, an a-like OS, a microcrystalline oxide semiconductor, and a CAAC-OS, for example.

The CAAC-OS film is formed, for example, by the following method.

For example, the CAAC-OS film is formed by a sputtering method with a polycrystalline oxide semiconductor sputtering target.

By increasing the substrate temperature during the deposition, migration of sputtered particles is likely to occur after the sputtered particles reach a substrate surface. Specifically, the substrate temperature during the deposition is higher than or equal to 100° C. and lower than or equal to 740° C., preferably higher than or equal to 200° C. and lower than or equal to 500° C. By increasing the substrate temperature during the deposition, when the sputtered particles reach the substrate, migration occurs on the substrate surface, so that a flat plane of the sputtered particles is attached to the substrate. At this time, the sputtered particle is charged positively, whereby sputtered particles are attached to the substrate while repelling each other; thus, the sputtered particles do not overlap with each other randomly, and a CAAC-OS film with a uniform thickness can be deposited.

By reducing the amount of impurities entering the CAAC-OS layer during the deposition, the crystal state can be prevented from being broken by the impurities. For example, the concentration of impurities (e.g., hydrogen, water, carbon dioxide, or nitrogen) that exist in the deposition chamber may be reduced. Furthermore, the concentration of impurities in a deposition gas may be reduced. Specifically, a deposition gas whose dew point is −80° C. or lower, preferably −100° C. or lower is used.

Furthermore, it is preferable that the proportion of oxygen in the deposition gas be increased and the power be optimized in order to reduce plasma damage at the deposition. The proportion of oxygen in the deposition gas is higher than or equal to 30 vol %, preferably 100 vol %.

Alternatively, the CAAC-OS film is formed by the following method.

First, a first oxide semiconductor film is formed to a thickness of greater than or equal to 1 nm and less than 10 nm. The first oxide semiconductor film is formed by a sputtering method. Specifically, the substrate temperature is set to higher than or equal to 100° C. and lower than or equal to 500° C., preferably higher than or equal to 150° C. and lower than or equal to 450° C., and the proportion of oxygen in a deposition gas is set to higher than or equal to 30 vol %, preferably 100 vol %.

Next, heat treatment is performed so that the first oxide semiconductor film becomes a first CAAC-OS film with high crystallinity. The temperature of the heat treatment is higher than or equal to 350° C. and lower than or equal to 740° C., preferably higher than or equal to 450° C. and lower than or equal to 650° C. The heat treatment time is longer than or equal to 1 minute and shorter than or equal to 24 hours, preferably longer than or equal to 6 minutes and shorter than or equal to 4 hours. The heat treatment may be performed in an inert atmosphere or an oxidation atmosphere. It is preferable to perform heat treatment in an inert atmosphere and then perform heat treatment in an oxidation atmosphere. The heat treatment in an inert atmosphere can reduce the concentration of impurities in the first oxide semiconductor film for a short time. At the same time, the heat treatment in an inert atmosphere may generate oxygen vacancies in the first oxide semiconductor film. In such a case, the heat treatment in an oxidation atmosphere can reduce the oxygen vacancies. Note that the heat treatment may be performed under a reduced pressure, such as 1000 Pa or lower, 100 Pa or lower, 10 Pa or lower, or 1 Pa or lower. The heat treatment under the reduced pressure can reduce the concentration of impurities in the first oxide semiconductor film for a shorter time.

The first oxide semiconductor film with a thickness greater than or equal to 1 nm and less than 10 nm can be easily crystallized by heat treatment as compared to the case where the first oxide semiconductor film has a thickness greater than or equal to 10 nm.

Next, a second oxide semiconductor film having the same composition as the first oxide semiconductor film is formed to a thickness of greater than or equal to 10 nm and less than or equal to 50 nm. The second oxide semiconductor film is formed by a sputtering method. Specifically, the substrate temperature is set to higher than or equal to 100° C. and lower than or equal to 500° C., preferably higher than or equal to 150° C. and lower than or equal to 450° C., and the proportion of oxygen in a deposition gas is set to higher than or equal to 30 vol %, preferably 100 vol %.

Next, heat treatment is performed so that solid phase growth of the second oxide semiconductor film is performed using the first CAAC-OS film, thereby forming a second CAAC-OS film with high crystallinity. The temperature of the heat treatment is higher than or equal to 350° C. and lower than or equal to 740° C., preferably higher than or equal to 450° C. and lower than or equal to 650° C. The heat treatment time is longer than or equal to 1 minute and shorter than or equal to 24 hours, preferably longer than or equal to 6 minutes and shorter than or equal to 4 hours. The heat treatment may be performed in an inert atmosphere or an oxidation atmosphere. It is preferable to perform heat treatment in an inert atmosphere and then perform heat treatment in an oxidation atmosphere. The heat treatment in an inert atmosphere can reduce the concentration of impurities in the second oxide semiconductor film for a short time. At the same time, the heat treatment in an inert atmosphere may generate oxygen vacancies in the second oxide semiconductor film. In such a case, the heat treatment in an oxidation atmosphere can reduce the oxygen vacancies. Note that the heat treatment may be performed under a reduced pressure, such as 1000 Pa or lower, 100 Pa or lower, 10 Pa or lower, or 1 Pa or lower. The heat treatment under the reduced pressure can reduce the concentration of impurities in the second oxide semiconductor film for a shorter time.

In the above-described manner, a CAAC-OS film with a total thickness of greater than or equal to 10 nm can be formed.

A display module of one embodiment of the present invention can be formed using an oxide semiconductor film having any of the above structures.

This embodiment can be combined with any of the other embodiments in this specification as appropriate.

### Embodiment 7

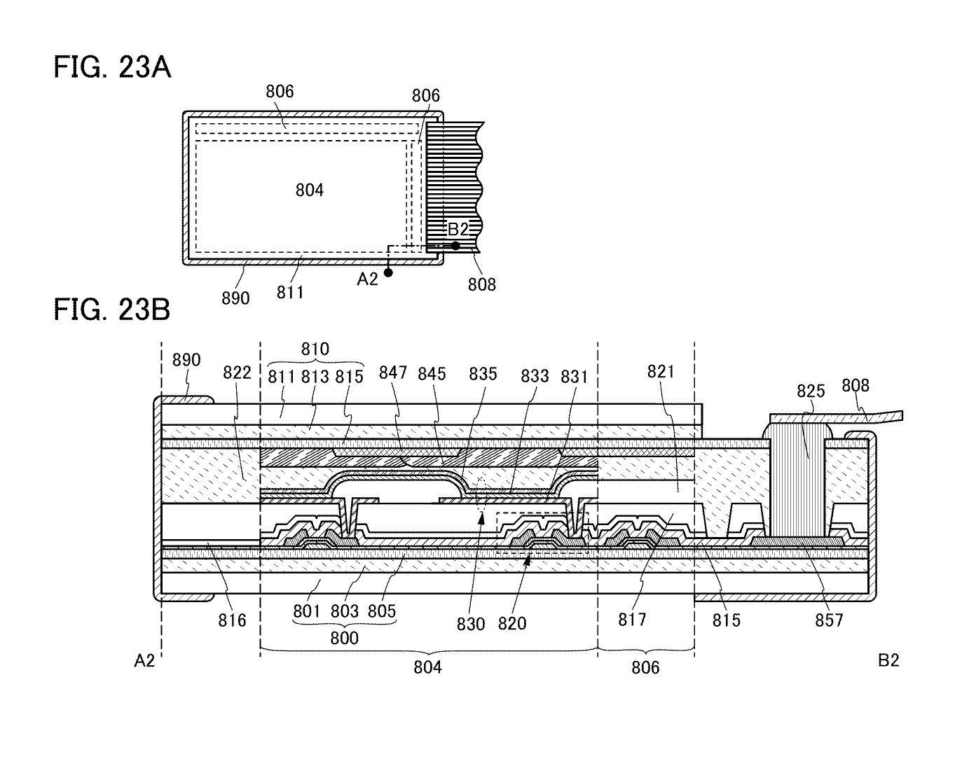

In this embodiment, the structure a display module of one embodiment of the present invention will be described with reference to FIGS. 23A and 23B.

FIGS. 23A and 23B illustrate the structure of a display module of one embodiment of the present invention. FIG. 23A is a top view of a display module of one embodiment of the present invention, and FIG. 23B is a cross-sectional view taken along the line A2-B2 in FIG. 23A.

The display module described in this embodiment is a top-emission display module using a color filter method. In this embodiment, the display module can have, for example, a structure in which sub-pixels of three colors of red (R), green (G), and blue (B) express one color, a structure in which sub-pixels of four colors of red (R), green (G), blue (B), and white (W) express one color, or a structure in which sub-pixels of four colors of red (R), green (G), blue (B), and yellow (Y) express one color. The color elements are not particularly limited and colors other than R, G, B, W, and Y may be used. For example, cyan or magenta may be used.

The display module shown in FIG. 23A includes an insulating layer 890, a display portion 804, operating circuit portions 806, and an FPC 808. The display portion 804 includes an organic EL element as a light-emitting element. The operating circuit portions 806 include a scan line driver circuit and a signal line driver circuit, for example.

In FIG. 23B, the display module includes a first base 800 (a substrate 801, an adhesive layer 803, and an insulating layer 805), a plurality of transistors, a terminal 857, an insulating layer 815, an insulating layer 816, an insulating layer 817, a plurality of light-emitting elements, an insulating layer 821, a bonding layer 822, a coloring layer 845, a light-blocking layer 847, and a second base 810 (an insulating layer 815, an adhesive layer 813, and a substrate 811). The bonding layer 822, the insulating layer 815, the adhesive layer 813, and the substrate 811 transmit visible light. Light-emitting elements and transistors included in the display portion 804 and the operating circuit portion 806 are sealed with the insulating layer 805, the insulating layer 815, and the bonding layer 822.

The display module described in this embodiment includes the insulating layer 890 that is in contact with the first base 800 supporting the terminal 857, the second base 810 overlapping with the first base 800, and the bonding layer 822 bonding the first base 800 to the second base 810. With such a structure, diffusion of impurities into a region surrounded by the insulating layer 890 can be suppressed. Accordingly, a novel display module with improved convenience or reliability can be provided.

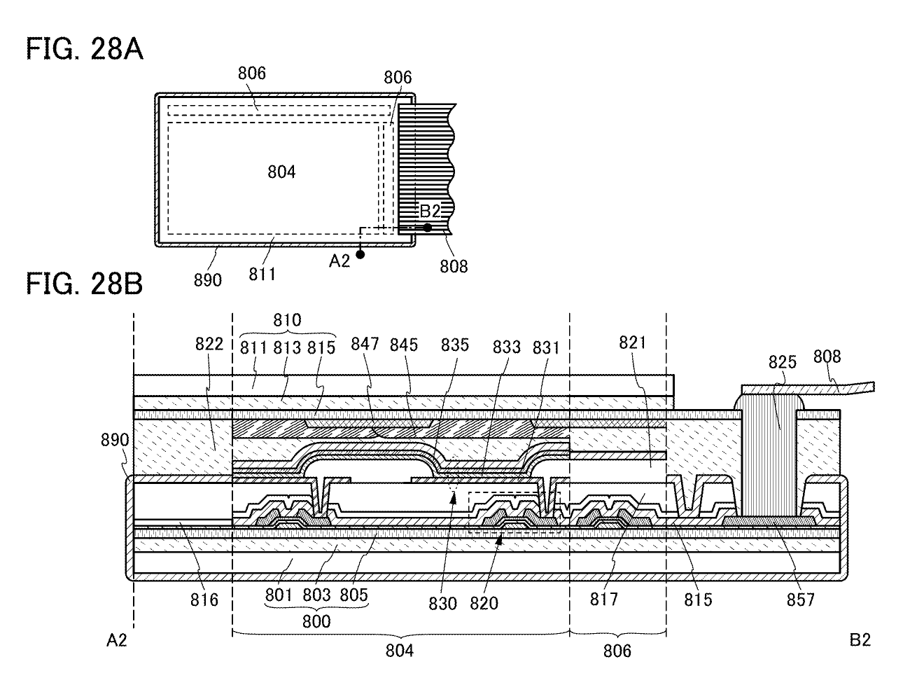

The insulating layer 890 may be formed such that the first base 800 and a light-emitting element 830 are included in the space surrounded by the insulating layer 890, as shown in FIGS. 28A and 28B.

The display portion 804 includes a transistor 820 and the light-emitting element 830 over the substrate 801 with the adhesive layer 803 and the insulating layer 805 provided between the substrate 801 and each of the transistor 820 and the light-emitting element 830. The light-emitting element 830 includes a lower electrode 831 over the insulating layer 817, an EL layer 833 over the lower electrode 831, and an upper electrode 835 over the EL layer 833. That is, the light-emitting element 830 includes the lower electrode 831, the upper electrode 835, and the EL layer 833 provided between the lower electrode 831 and the upper electrode 835.

The lower electrode 831 is electrically connected to a source electrode or a drain electrode of the transistor 820. An end portion of the lower electrode 831 is covered with the insulating layer 821. The lower electrode 831 preferably reflects visible light. The upper electrode 835 transmits visible light.

In addition, the display portion 804 includes the coloring layer 845 overlapping with the light-emitting element 830 and the light-blocking layer 847 overlapping with the insulating layer 821. The space between the light-emitting element 830 and the coloring layer 845 is filled with the bonding layer 822.

The insulating layer 815 and the insulating layer 816 have an effect of inhibiting diffusion of impurities to a semiconductor included in the transistors. As the insulating layer 817, an insulating layer having a planarization function is preferably selected in order to reduce surface unevenness due to the transistor.

The operating circuit portion 806 includes a plurality of transistors over the substrate 801 with the adhesive layer 803 and the insulating layer 805 provided therebetween. In FIG. 23B, one of the transistors included in the operating circuit portion 806 is shown.

The insulating layer 805 and the insulating layer 815 are preferably highly resistant to moisture, in which case entry of impurities such as water into the light-emitting element 830 or the transistor 820 can be inhibited, leading to higher reliability of the display module. When the display module includes a substrate, the surface of the display module can be protected from a physical impact, which is preferable. The substrate 801 is bonded to the insulating layer 805 with the adhesive layer 803. The substrate 811 is bonded to the insulating layer 815 with the adhesive layer 813.

The terminal 857 is electrically connected to an external electrode through which a signal (e.g., a video signal, a clock signal, a start signal, or a reset signal) or a potential from the outside is transmitted to the operating circuit portion 806. Here, an example in which the FPC 808 is provided as the external electrode is described. To prevent an increase in the number of manufacturing steps, the terminal 857 is preferably formed using the same material and the same step(s) as those of the electrode or the wiring in the display portion or the driver circuit portion. Here, an example is described in which the terminal 857 is formed using the same material and the same step(s) as those of the electrodes of the transistor 820.

In the display module in FIG. 23B, the FPC 808 is positioned over the insulating layer 815. A connector 825 is connected to the terminal 857 through an opening provided in the insulating layer 815, the bonding layer 822, the insulating layer 817, and the insulating layer 816. The connector 825 is also connected to the FPC 808. The FPC 808 and the terminal 857 are electrically connected to each other via the connector 825.

### <Examples of Materials and Formation Method>

Next, materials and the like that can be used for the display module will be described. Note that description on the components already described in this specification will be omitted in some cases.

For each of the substrates, a material such as glass, quartz, an organic resin, a metal, or an alloy can be used. The substrate on the side from which light from the light-emitting element is extracted is formed using a material which transmits the light.

It is particularly preferable to use a flexible substrate. For example, an organic resin; a glass material, a metal, or an alloy that is thin enough to have flexibility; or the like can be used.

An organic resin, which has a specific gravity smaller than that of glass, is preferably used for the flexible substrate, in which case the display module can be lightweight as compared with the case where glass is used.

The substrates are preferably formed using a material with high toughness, in which case a display module with high impact resistance that is less likely to be broken can be provided. For example, when an organic resin substrate or a thin metal or alloy substrate is used, the display module can be lighter in weight and more robust than that using a glass substrate.

A metal material and an alloy material, which have high thermal conductivity, are preferred because they can easily conduct heat to the whole substrate and accordingly can prevent a local temperature rise in the display module. The thickness of a substrate using a metal material or an alloy material is preferably greater than or equal to 10 μm and less than or equal to 200 μm, further preferably greater than or equal to 20 μm and less than or equal to 50 μm.

There is no particular limitation on a material of the metal substrate or the alloy substrate, but it is preferable to use, for example, aluminum, copper, nickel, a metal alloy such as an aluminum alloy or stainless steel.

Furthermore, when a material with high thermal emissivity is used for the substrate, the surface temperature of the display module can be prevented from rising, leading to inhibition of breakage or a decrease in reliability of the display module. For example, the substrate may have a stacked-layer structure of a metal substrate and a layer with high thermal emissivity (e.g., the layer can be formed using a metal oxide or a ceramic material).

As the substrate having flexibility and a light-transmitting property, a plastic substrate that is formed as a film, for example, a plastic substrate made from polyimide (PI), an aramid, polyethylene terephthalate (PET), polyethersulfone (PES), polyethylene naphthalate (PEN), polycarbonate (PC), nylon, polyetheretherketone (PEEK), polysulfone (PSF), polyetherimide (PEI), polyarylate (PAR), polybutylene terephthalate (PBT), a silicone resin, and the like can be used. The substrate may contain a fiber or the like (e.g., a prepreg). Furthermore, the substrate is not limited to the resin film, and a transparent nonwoven fabric formed by processing pulp into a continuous sheet, a sheet including an artificial spider's thread fiber containing protein called fibroin, a complex in which the transparent nonwoven fabric or the sheet and a resin are mixed, a stack of a resin film and a nonwoven fabric containing a cellulose fiber whose fiber width is 4 nm or more and 100 nm or less, or a stack of a resin film and a sheet including an artificial spider's thread fiber may be used.

The flexible substrate may have a stacked-layer structure in which a hard coat layer (such as a silicon nitride layer) by which a surface of a device is protected from damage, a layer (such as an aramid resin layer) which can disperse pressure, or the like is stacked over a layer of any of the above-mentioned materials.

The flexible substrate may be formed by stacking a plurality of layers. In particular, when a glass layer is used, barrier properties against water and oxygen can be improved and thus a reliable display module can be provided.

A flexible substrate in which a glass layer, an adhesive layer, and an organic resin layer are stacked from the side closer to a light-emitting element is preferably used. The thickness of the glass layer is greater than or equal to 20 μm and less than or equal to 200 μm, preferably greater than or equal to 25 μm and less than or equal to 100 μm. With such a thickness, the glass layer can have both a high barrier property against water and oxygen, and flexibility. The thickness of the organic resin layer is greater than or equal to 10 μm and less than or equal to 200 μm, preferably greater than or equal to 20 μm and less than or equal to 50 μm. The provision of such organic resin layer can suppress occurrence of a crack or a break in the glass layer and improve the mechanical strength. With the substrate that includes such a composite material of a glass material and an organic resin, a highly reliable flexible display module can be provided.

Here, a method for forming a flexible display module is described.

For convenience, a structure including a pixel and a driver circuit, a structure including an optical member such as a color filter, a structure including a touch sensor, or a structure including a functional member is referred to as an element layer. An element layer includes a display element, for example, and may include a wiring electrically connected to the display element or an element such as a transistor used in a pixel or a circuit in addition to the display element.

Here, a support provided with an insulating surface over which an element layer is formed is called a base.

As a method for forming an element layer over a flexible base, there are a method in which an element layer is formed directly on a flexible base; and a method in which an element layer is formed over a supporting base that has stiffness, and then the element layer is separated from the supporting base and transferred to a flexible base.

In the case where a material of the base can withstand heating temperature in the process for forming the element layer, it is preferable that the element layer be formed directly over the base, in which case a manufacturing process can be simplified. At this time, the element layer is preferably formed in a state where the base is fixed to the supporting base, in which case the transfer of the element layer in a device and between devices can be easy.

In the case where the method is employed in which the element layer is formed over a supporting base and then transferred to a flexible base, first, a separation layer and an insulating layer are stacked over the supporting base, and then the element layer is formed over the insulating layer. Then, the element layer is separated from the supporting base and then transferred to the flexible base. At this time, a material of the separation layer is selected such that separation at an interface between the supporting base and the separation layer, at an interface between the separation layer and the insulating layer, or in the separation layer occurs. With such a method, the element layer can be formed at temperatures higher than the upper temperature limit of the base, which can improve the reliability of the display module.

It is preferable that stacked layers including a layer containing a high-melting-point metal material, such as tungsten, and a layer containing an oxide of the metal material be used as the separation layer, and stacked layers including a plurality of layers, such as a silicon nitride layer and a silicon oxynitride layer, be used as the insulating layer over the separation layer, for example. The use of a high-melting-point metal material enables a high-temperature process to be performed in forming the element layer, resulting in high reliability. For example, impurities contained in the element layer can be further reduced, and the crystallinity of a semiconductor or the like included in the element layer can be further increased.

Examples of the separation method include peeling off by application of mechanical power, removal of the separation layer by etching, or separation by dripping of a liquid into part of the separation interface to penetrate the entire separation interface.

The separation layer need not be provided in the case where separation can occur at an interface between the supporting base and the insulating layer. For example, glass may be used as the supporting base, an organic resin such as polyimide may be used as the insulating layer, a separation trigger may be formed by locally heating part of the organic resin by laser light or the like, and separation may be performed at an interface between the glass and the insulating layer. Alternatively, it is possible that a layer containing a material with high thermal conductivity (e.g., a metal or a semiconductor) is provided between the supporting base and the insulating layer containing an organic resin, and this layer is heated by current so that separation easily occurs, and then separation is performed. In this case, the insulating layer containing an organic resin can also be used as the base.

As the adhesive layer, a variety of curable resins such as a reactive curable resin, a thermosetting resin, an anaerobic resin, and a photo curable resin such as an ultraviolet curable resin can be used. Examples of such resins include an epoxy resin, an acrylic resin, a silicone resin, a phenol resin, a polyimide resin, an imide resin, a polyvinyl chloride (PVC) resin, a polyvinyl butyral (PVB) resin, an ethylene vinyl acetate (EVA) resin, and the like. In particular, a material with low moisture permeability, such as an epoxy resin, is preferred. Alternatively, a two-component-mixture-type resin may be used. Further alternatively, an adhesive sheet or the like may be used.

Further, the resin may contain a drying agent. As the drying agent, for example, a substance which adsorbs moisture by chemical adsorption, such as an oxide of an alkaline earth metal (e.g., calcium oxide or barium oxide), can be used. Alternatively, a substance that adsorbs moisture by physical adsorption, such as zeolite or silica gel, may be used. The drying agent is preferably contained, in which case entry of impurities such as moisture can be inhibited and the reliability of the display module can be improved.

In addition, it is preferable to mix a filler with a high refractive index or light-scattering member into the resin, in which case the efficiency of light extraction from the light-emitting element can be improved. For example, titanium oxide, barium oxide, zeolite, zirconium, or the like can be used.

Insulating films with excellent moisture-proof properties are preferably used for the insulating layer 805 and the insulating layer 815. Alternatively, the insulating layer 805 and the insulating layer 815 preferably have a function of preventing diffusion of impurities to a light-emitting element.

As an insulating film having an excellent moisture-proof property, a film containing nitrogen and silicon (e.g., a silicon nitride film, a silicon nitride oxide film, or the like), a film containing nitrogen and aluminum (e.g., an aluminum nitride film or the like), or the like can be used. Alternatively, a silicon oxide film, a silicon oxynitride film, an aluminum oxide film, or the like can be used.

The water vapor transmittance of the insulating film having an excellent moisture-proof property is lower than or equal to 1×10⁻⁵ [g/(m²·day)], preferably lower than or equal to 1×10⁻⁶ [g/(m²·day)], further preferably lower than or equal to 1×10⁻⁷ [g/(m²·day)], or still further preferably lower than or equal to 1×10⁻⁸ [g/(m²·day)], for example.

In the display module, it is necessary that at least one of the insulating layers 805 and 815, which is on the light-emitting surface side, transmit light emitted from the light-emitting element. In the case where the display module includes the insulating layers 805 and 815, one of the insulating layers 805 and 815, which transmits light emitted from the light-emitting element, preferably has higher average transmittance than the other in a wavelength range of 400 nm to 800 nm inclusive.

The insulating layers 805 and 815 each preferably contain oxygen, nitrogen, and silicon. The insulating layers 805 and 815 each preferably contain, for example, silicon oxynitride. Moreover, the insulating layers 805 and 815 each preferably contain silicon nitride or silicon nitride oxide. It is preferable that the insulating layers 805 and 815 be each formed using a silicon oxynitride film and a silicon nitride film, which are in contact with each other. The silicon oxynitride film and the silicon nitride film are alternately stacked such that antiphase interference occurs more often in a visible region, whereby the stack can have higher transmittance of light in the visible region.

For the materials and formation method of the insulating layer 890, the description of the insulating layer 290 in Embodiment 1 can be referred to. Materials similar to those for the insulating layers 805 and 815 can also be used for the insulating layer 890.

The structure of the transistors in the display module is not particularly limited. For example, a forward staggered transistor or an inverted staggered transistor may be used. A top-gate transistor or a bottom-gate transistor may be used. A semiconductor material used for the transistors is not particularly limited, and for example, silicon, germanium, or an organic semiconductor can be used. Alternatively, an oxide semiconductor containing at least one of indium, gallium, and zinc, such as an In—Ga—Zn-based metal oxide, may be used. For the structural example of the transistor including an oxide semiconductor, the description in the above embodiment of the transistor can be referred to.

For stable characteristics of the transistor, a base film is preferably provided. The base film can be formed with an inorganic insulating film such as a silicon oxide film, a silicon nitride film, a silicon oxynitride film, or a silicon nitride oxide film to have a single-layer structure or a stacked-layer structure. The base film can be formed by a sputtering method, a chemical vapor deposition (CVD) method (e.g., a plasma CVD method, a thermal CVD method, or a metal organic CVD (MOCVD) method), an atomic layer deposition (ALD) method, a coating method, a printing method, or the like. Note that the base film may not be provided if not necessary. In each of the above structural examples, the insulating layer 805 can serve as a base film of the transistor.

As the light-emitting element, a self-luminous element can be used, and an element whose luminance is controlled by current or voltage is included in the category of the light-emitting element. For example, a light-emitting diode (LED), an organic EL element, an inorganic EL element, or the like can be used.

The light-emitting element may be a top emission, bottom emission, or dual emission light-emitting element. A conductive film that transmits visible light is used as the electrode through which light is extracted. A conductive film that reflects visible light is preferably used as the electrode through which light is not extracted.

The conductive film that transmits visible light can be formed using, for example, indium oxide, indium tin oxide (ITO), indium zinc oxide, zinc oxide (ZnO), or zinc oxide to which gallium is added. Alternatively, a film of a metal material such as gold, silver, platinum, magnesium, nickel, tungsten, chromium, molybdenum, iron, cobalt, copper, palladium, or titanium; an alloy containing any of these metal materials; or a nitride of any of these metal materials (e.g., titanium nitride) can be formed thin so as to have a light-transmitting property. Alternatively, a stack of any of the above materials can be used as the conductive layer. For example, a stacked film of ITO and an alloy of silver and magnesium is preferably used, in which case conductivity can be increased. Further alternatively, graphene or the like may be used.

For the conductive film that reflects visible light, for example, a metal material, such as aluminum, gold, platinum, silver, nickel, tungsten, chromium, molybdenum, iron, cobalt, copper, or palladium or an alloy containing any of these metal materials can be used. Lanthanum, neodymium, germanium, or the like may be added to the metal material or the alloy. Furthermore, an alloy containing aluminum (an aluminum alloy) such as an alloy of aluminum and titanium, an alloy of aluminum and nickel, an alloy of aluminum and neodymium, or an alloy of aluminum, nickel, and lanthanum (Al—Ni—La), or an alloy containing silver such as an alloy of silver and copper, an alloy of silver, palladium, and copper (Ag—Pd—Cu, also referred to as APC), or an alloy of silver and magnesium can be used for the conductive film. An alloy of silver and copper is preferable because of its high heat resistance. Moreover, a metal film or a metal oxide film may be stacked on an aluminum alloy film, whereby oxidation of the aluminum alloy film can be suppressed. Examples of a material for the metal film or the metal oxide film are titanium and titanium oxide. Alternatively, the conductive film having a property of transmitting visible light and a film containing any of the above metal materials may be stacked. For example, a stacked film of silver and ITO or a stacked film of an alloy of silver and magnesium and ITO can be used.

The lower electrode 831 and the upper electrode 835 can be formed of the conductive film that transmits visible light or the conductive film that reflects visible light.

The electrodes may be each formed by an evaporation method or a sputtering method. Alternatively, a discharging method such as an ink-jet method, a printing method such as a screen printing method, or a plating method may be used.

When a voltage higher than the threshold voltage of the light-emitting element is applied between the lower electrode 831 and the upper electrode 835, holes are injected to the EL layer 833 from the anode side and electrons are injected to the EL layer 833 from the cathode side. The injected electrons and holes recombine in the EL layer 833 and a light-emitting substance contained in the EL layer 833 emits light.

The EL layer 833 includes at least a light-emitting layer. In addition to the light-emitting layer, the EL layer 833 may further include one or more layers containing any of a substance with a high hole-injection property, a substance with a high hole-transport property, a hole-blocking material, a substance with a high electron-transport property, a substance with a high electron-injection property, a substance with a bipolar property (a substance with a high electron- and hole-transport property), and the like.

For the EL layer 833, either a low molecular compound or a high molecular compound can be used, and an inorganic compound may also be used. The above-described layers included in the EL layer 833 can be each formed by any of the following methods: an evaporation method (including a vacuum evaporation method), a transfer method, a printing method, an inkjet method, a coating method, and the like.

The light-emitting element 830 may contain two or more kinds of light-emitting substances. Thus, for example, a light-emitting element that emits white light can be achieved. For example, light-emitting substances are selected so that two or more light-emitting substances emit complementary colors to obtain white light emission. A light-emitting substance that emits red (R) light, green (G) light, blue (B) light, yellow (Y) light, or orange (O) light or a light-emitting substance that emits light containing spectral components of two or more of R light, G light, and B light can be used, for example. A light-emitting substance that emits blue light and a light-emitting substance that emits yellow light may be used, for example. At this time, the emission spectrum of the light-emitting substance that emits yellow light preferably contains spectral components of G light and R light. The emission spectrum of the light-emitting element 830 preferably has two or more peaks in the wavelength range in a visible region (e.g., greater than or equal to 350 nm and less than or equal to 750 nm or greater than or equal to 400 nm and less than or equal to 800 nm).

The EL layer 833 may include a plurality of light-emitting layers. In the EL layer 833, the plurality of light-emitting layers may be stacked in contact with one another or may be stacked with a separating layer provided therebetween. The separating layer may be provided between a fluorescent layer and a phosphorescent layer, for example.

The separating layer can be provided, for example, to prevent energy transfer by the Dexter mechanism (particularly triplet energy transfer) from a phosphorescent material or the like in an excited state which is generated in the phosphorescent layer to a fluorescent material or the like in the fluorescent layer. The thickness of the separating layer may be several nanometers. Specifically, the thickness of the separating layer may be greater than or equal to 0.1 nm and less than or equal to 20 nm, greater than or equal to 1 nm and less than or equal to 10 nm, or greater than or equal to 1 nm and less than or equal to 5 nm. The separating layer contains a single material (preferably, a bipolar substance) or a plurality of materials (preferably, a hole-transport material and an electron-transport material).

The separating layer may be formed using a material contained in a light-emitting layer in contact with the separating layer. This facilitates the manufacture of the light-emitting element and reduces the drive voltage. For example, in the case where the phosphorescent layer contains a host material, an assist material, and the phosphorescent material (a guest material), the separating layer may contain the host material and the assist material. In other words, the separating layer has a region not containing the phosphorescent material and the phosphorescent layer has a region containing the phosphorescent material in the above structure. Accordingly, the separating layer and the phosphorescent layer can be evaporated separately through selecting whether or not a phosphorescent material is used. With such a structure, the separating layer and the phosphorescent layer can be formed in the same chamber, whereby the manufacturing cost can be reduced.

Moreover, the light-emitting element 830 may be a single element including one EL layer or a tandem element in which EL layers are stacked with a charge generation layer provided therebetween.

The light-emitting element is preferably surrounded by an insulating film having an excellent moisture-proof property. With such a structure, entry of impurities such as water into the light-emitting element can be inhibited, and decrease in reliability of the display module can be prevented.

As each of the insulating layer 815 and the insulating layer 816, for example, an inorganic insulating film such as a silicon oxide film, a silicon oxynitride film, or an aluminum oxide film can be used. Note that the insulating layer 815 and the insulating layer 816 may be formed using different materials. As the insulating layer 817, for example, an organic material such as polyimide, acrylic, polyamide, polyimide amide, or a benzocyclobutene-based resin can be used. Alternatively, a low-dielectric constant material (a low-k material) or the like can be used. Furthermore, each insulating layer may be formed by stacking a plurality of insulating layers.

The insulating layer 821 is formed using an organic insulating material or an inorganic insulating material. As the resin, for example, a polyimide resin, a polyamide resin, an acrylic resin, a siloxane resin, an epoxy resin, or a phenol resin can be used. It is particularly preferable that the insulating layer 821 be formed using a photosensitive resin material to have an opening portion over the lower electrode 831 such that a side wall of the opening portion is formed as an inclined surface with a continuous curvature.

There is no particular limitation on the method for forming the insulating layer 821; a photolithography method, a sputtering method, an evaporation method, a droplet discharging method (e.g., an ink-jet method), a printing method (e.g., a screen printing method or an off-set printing method), or the like may be used.

A conductive layer functioning as an electrode or a wiring of the transistor, an auxiliary wiring of the light-emitting element or the like, used in the display module, can be formed to have a single-layer structure or a layered structure using any of metal materials such as molybdenum, titanium, chromium, tantalum, tungsten, aluminum, copper, neodymium, and scandium, and an alloy material containing any of these elements, for example. Alternatively, the conductive layer may be formed using a conductive metal oxide. As the conductive metal oxide, indium oxide (e.g., In₂O₃), tin oxide (e.g., SnO₂), ZnO, ITO, indium zinc oxide (e.g., In₂O₃—ZnO), or any of these metal oxide materials in which silicon oxide is contained can be used.

The coloring layer is a colored layer that transmits light in a specific wavelength range. For example, a color filter for transmitting light in a red, green, blue, or yellow wavelength range can be used. Each coloring layer is formed in a desired position with any of various materials by a printing method, an inkjet method, an etching method using a photolithography method, or the like. In a white sub-pixel, a resin such as a transparent resin or a white resin may be provided so as to overlap with the light-emitting element.

The light-blocking layer is provided between adjacent coloring layers. The light-blocking layer blocks light emitted from an adjacent light-emitting element to prevent color mixture between adjacent light-emitting elements. Here, the coloring layer is provided such that its end portion overlaps with the light-blocking layer, whereby light leakage can be reduced. As the light-blocking layer, a material that can block light from the light-emitting element can be used; for example, a black matrix may be formed using a resin material containing a metal material, pigment, or dye. Note that it is preferable to provide the light-blocking layer in a region other than the display portion, such as a driver circuit portion, in which case undesired leakage of guided light or the like can be inhibited.

Furthermore, an overcoat covering the coloring layer and the light-blocking layer may be provided. The overcoat can prevent an impurity and the like contained in the coloring layer from being diffused into the light-emitting element. The overcoat is formed using a material that transmits light emitted from the light-emitting element; for example, an inorganic insulating film such as a silicon nitride film or a silicon oxide film, an organic insulating film such as an acrylic film or a polyimide film can be used, and further, a stacked structure of an organic insulating film and an inorganic insulating film may be employed.

In the case where upper surfaces of the coloring layer and the light-blocking layer are coated with a material of an adhesive layer, a material that has high wettability with respect to the material of the adhesive layer is preferably used as the material of the overcoat. For example, an oxide conductive film such as an ITO film or a metal film such as an Ag film that is thin enough to transmit light is preferably used as the overcoat.

As the connector, any of a variety of anisotropic conductive films (ACF), anisotropic conductive pastes (ACP), and the like can be used.

This embodiment can be combined with any of the other embodiments in this specification as appropriate.

### Embodiment 8

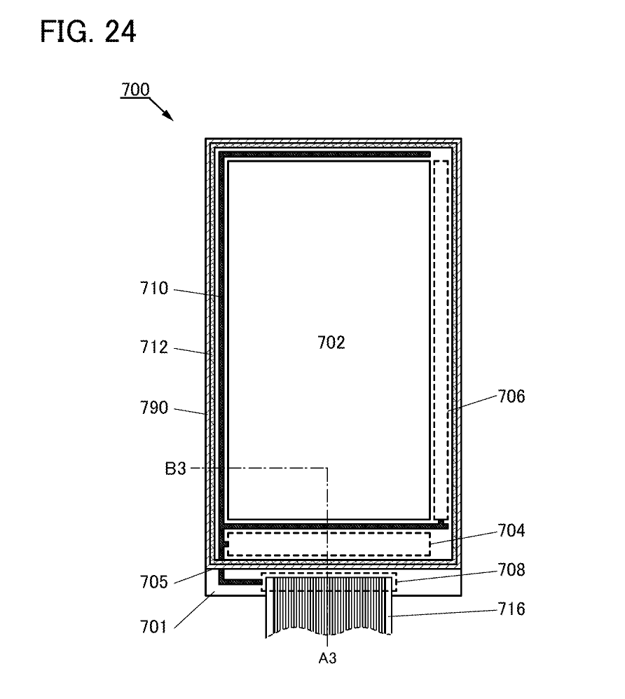

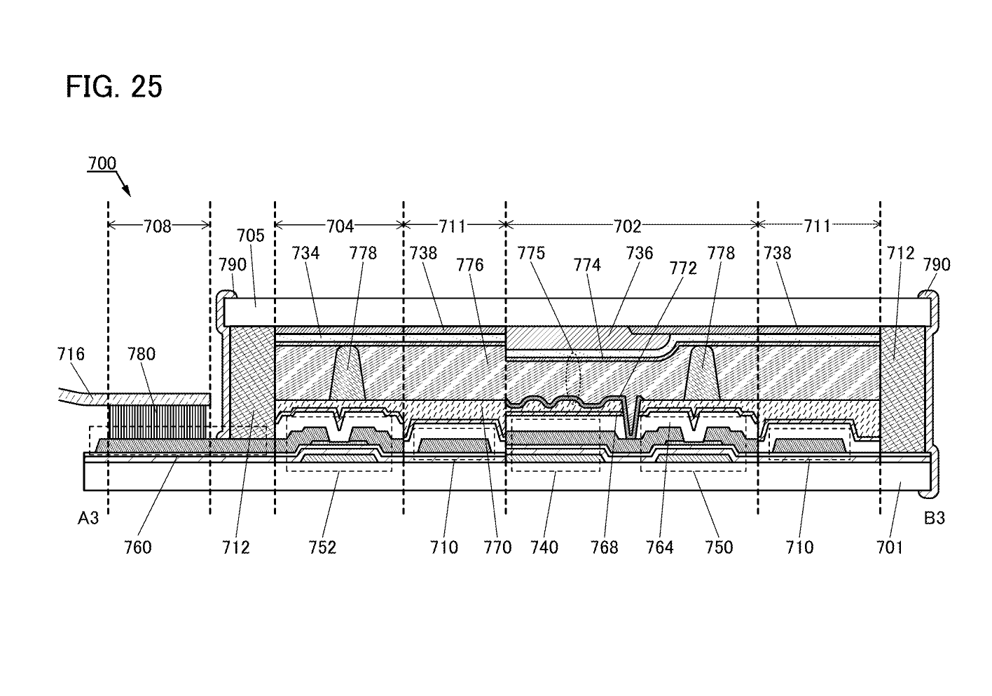

In this embodiment, the structure of a display module of one embodiment of the present invention, which is different from Embodiment 7, will be described with reference to FIG. 24 and FIG. 25.

FIG. 24 is a top view of a display module of one embodiment of the present invention. A display module 700 shown in FIG. 24 includes a pixel portion 702 provided over a first base 701; a source driver circuit portion 704 and a gate driver circuit portion 706 provided over the first base 701; a bonding layer 712 provided to surround the pixel portion 702, the source driver circuit portion 704, and the gate driver circuit portion 706; a second base 705 provided to face the first base 701; and an insulating layer 790 provided to surround the bonding layer 712. The first base 701 and the second base 705 are sealed with the bonding layer 712 and the insulating layer 790. That is, the pixel portion 702, the source driver circuit portion 704, and the gate driver circuit portion 706 are sealed with the first base 701, the bonding layer 712, the insulating layer 790, and the second base 705. Although not illustrated in FIG. 24, a display element is provided between the first base 701 and the second base 705.

In the display module 700, a flexible printed circuit (FPC) terminal portion 708 electrically connected to the pixel portion 702, the source driver circuit portion 704, and the gate driver circuit portion 706 is provided in a region different from the region that is surrounded by the bonding layer 712 and positioned over the first base 701. Furthermore, an FPC 716 is connected to the FPC terminal portion 708, and a variety of signals and the like are supplied to the pixel portion 702, the source driver circuit portion 704, and the gate driver circuit portion 706 through the FPC 716. Furthermore, a signal line 710 is connected to the pixel portion 702, the source driver circuit portion 704, the gate driver circuit portion 706, and the FPC terminal portion 708. Various signals and the like are applied to the pixel portion 702, the source driver circuit portion 704, the gate driver circuit portion 706, and the FPC terminal portion 708 via the signal line 710 from the FPC 716.

A plurality of gate driver circuit portions 706 may be provided in the display module 700. An example of the display module 700 in which the source driver circuit portion 704 and the gate driver circuit portion 706 are formed over the first base 701 where the pixel portion 702 is also formed is described; however, the structure is not limited thereto. For example, only the gate driver circuit portion 706 may be formed over the first base 701 or only the source driver circuit portion 704 may be formed over the first base 701. In this case, a substrate where a source driver circuit, a gate driver circuit, or the like is formed (e.g., a driver-circuit substrate formed using a single-crystal semiconductor film or a polycrystalline semiconductor film) may be mounted on the first base 701. Note that there is no particular limitation on the method of connecting a separately prepared driver-circuit substrate, and a chip on glass (COG) method, a wire bonding method, or the like can be used.

The pixel portion 702, the source driver circuit portion 704, and the gate driver circuit portion 706 included in the display module 700 include a plurality of transistors. As the plurality of transistors, any of the transistors that are described in the above embodiments can be used.

The display module 700 can a liquid crystal element. Examples of display devices including the liquid crystal elements include a liquid crystal display (e.g., a transmissive liquid crystal display, a transflective liquid crystal display, a reflective liquid crystal display, a direct-view liquid crystal display, or a projection liquid crystal display). For a transflective liquid crystal display or a reflective liquid crystal display, some of or all of pixel electrodes function as reflective electrodes. For example, some or all of pixel electrodes are formed to contain aluminum, silver, or the like. In such a case, a memory circuit such as an SRAM can be provided under the reflective electrodes, leading to lower power consumption.

As a display method in the display module 700, a progressive method, an interlace method, or the like can be employed. Further, color elements controlled in a pixel at the time of color display are not limited to three colors: R, G, and B (R, G, and B correspond to red, green, and blue, respectively). For example, a display unit may be composed of four pixels of the R pixel, the G pixel, the B pixel, and a W (white) pixel. Alternatively, a display unit may be composed of two of color elements among R, G, and B as in PenTile layout. The two colors may differ among display units. Alternatively, one or more colors of yellow, cyan, magenta, and the like may be added to RGB. Note that the sizes of display regions may be different between respective dots of color elements. Embodiments of the disclosed invention are not limited to a display device for color display; the disclosed invention can also be applied to a display device for monochrome display.

A coloring layer (also referred to as a color filter) may be used in order to obtain a full-color display device in which white light (W) for a backlight (e.g., an organic EL element, an inorganic EL element, an LED, or a fluorescent lamp) is used. As the coloring layer, red (R), green (G), blue (B), yellow (Y), or the like may be combined as appropriate, for example. With the use of the coloring layer, higher color reproducibility can be obtained than in the case without the coloring layer. In this case, by providing a region with the coloring layer and a region without the coloring layer, white light in the region without the coloring layer may be directly utilized for display. By partly providing the region without the coloring layer, a decrease in luminance due to the coloring layer can be suppressed, and 20% to 30% of power consumption can be reduced in some cases when an image is displayed brightly. Note that in the case where full-color display is performed using a self-luminous element such as an organic EL element or an inorganic EL element, elements may emit light of their respective colors R, G, B, Y, and W. By using a self-luminous element, power consumption may be further reduced as compared with the case where the coloring layer is used. Note that in this embodiment, a structure in which a backlight and the like are not provided, that is, a so-called reflective liquid crystal display module will be described below.

FIG. 25 shows a cross-sectional view taken along the dashed-dotted line A3-B3 in FIG. 24. The display module illustrated in FIG. 25 will be described in detail below.

### <Display Module>

The display module 700 shown in FIG. 25 includes a lead wiring portion 711, the pixel portion 702, the source driver circuit portion 704, and the FPC terminal portion 708. Note that the lead wiring portion 711 includes a signal line 710. The pixel portion 702 includes a transistor 750 and a capacitor 740. The source driver circuit portion 704 includes a transistor 752.

Any of the transistors described above can be used as the transistors 750 and 752.

The transistors used in this embodiment each include an oxide semiconductor film which is highly purified and in which formation of oxygen vacancies is suppressed. In the transistor, the current in an off state (off-state current) can be made small. Accordingly, an electrical signal such as an image signal can be held for a longer period, and a writing interval can be set longer in an on state. Thus, frequency of refresh operation can be reduced, which leads to an effect of suppressing power consumption.

In addition, the transistor used in this embodiment can have relatively high field-effect mobility and thus is capable of high speed operation. For example, with such a transistor that can operate at high speed used for a liquid crystal display device, a switching transistor in a pixel portion and a driver transistor in a driver circuit portion can be formed over one substrate. That is, a semiconductor device formed using a silicon wafer or the like is not additionally needed as a driver circuit, by which the number of components of the semiconductor device can be reduced. In addition, the transistor that can operate at high speed can be used also in the pixel portion, whereby a high-quality image can be provided.

The capacitor 740 includes a dielectric between a pair of electrodes. Specifically, a conductive film which is formed using the same step as a conductive film that functions as a gate electrode of the transistor 750 is used as one electrode of the capacitor 740, and a conductive film that functions as a source electrode or a drain electrode of the transistor 750 is used as the other electrode of the capacitor 740. Furthermore, an insulating layer functioning as a gate insulating layer of the transistor 750 is used as the dielectric between the pair of electrodes.

In FIG. 25, insulating layers 764 and 768 and a planarization insulating layer 770 are formed over the transistor 750, the transistor 752, and the capacitor 740.

As the insulating layer 764, a silicon oxide film, a silicon oxynitride film, or the like may be formed by a PECVD device, for example. As the insulating layer 768, a silicon nitride film or the like may be formed by a PECVD device, for example. The planarization insulating layer 770 can be formed using a heat-resistant organic material, such as a polyimide resin, an acrylic resin, a polyimide amide resin, a benzocyclobutene resin, a polyamide resin, or an epoxy resin. Note that the planarization insulating layer 770 may be formed by stacking a plurality of insulating layers formed from these materials. Alternatively, a structure without the planarization insulating layer 770 may be employed. For the materials and formation method of the insulating layer 790, the description of the insulating layer 290 in Embodiment 1 can be referred to. Alternatively, materials similar to those of the insulating layer 764 or the insulating layer 768 may be used for the insulating layer 790.

The signal line 710 is formed in the same process as conductive films functioning as a source electrode and a drain electrode of the transistor 750 or 752. Note that the signal line 710 may be formed using a conductive film which is formed in a different process from a source electrode and a drain electrode of the transistor 750 or 752, e.g., a conductive film functioning as a gate electrode may be used. In the case where the signal line 710 is formed using a material containing a copper element, signal delay or the like due to wiring resistance is reduced, which enables display on a large screen.

The FPC terminal portion 708 includes a terminal 760, an anisotropic conductive film 780, and the FPC 716. Note that the terminal 760 is formed in the same process as conductive films functioning as a source electrode and a drain electrode of the transistor 750 or 752. The terminal 760 is electrically connected to a terminal included in the FPC 716 through the anisotropic conductive film 780.

A glass substrate can be used as the first base 701 and the second base 705, for example. A flexible substrate may be used as the first base 701 and the second base 705. Examples of the flexible substrate include a plastic substrate.

A structure 778 is provided between the first base 701 and the second base 705. The structure 778 is a columnar spacer obtained by selective etching of an insulating layer and provided to control the distance (cell gap) between the first base 701 and the second base 705. Alternatively, a spherical spacer may be used as the structure 778. Although the structure in which the structure 778 is provided on the first base 701 side is described as an example in this embodiment, one embodiment of the present invention is not limited thereto. For example, a structure in which the structure 778 is provided on the second base 705 side, or a structure in which each of the first base 701 and the second base 705 is provided with the structure 778 may be employed.

Furthermore, a light-blocking film 738 functioning as a black matrix, a coloring film 736 functioning as a color filter, and an insulating layer 734 in contact with the light-blocking film 738 and the coloring film 736 are provided on the second base 705 side.

The display module described in this embodiment includes the insulating layer 790 that is in contact with the first base 701 supporting the terminal 760, the second base 705 overlapping with the first base 701, and the bonding layer 712 bonding the first base 701 to the second base 705. With such a structure, diffusion of impurities into a region surrounded by the insulating layer 790 can be suppressed. Accordingly, a novel display module with improved convenience or reliability can be provided.

### <Structural Example of Liquid Crystal Element as Display Element>

The display module 700 illustrated in FIG. 25 includes a liquid crystal element 775. The liquid crystal element 775 includes a conductive film 772, a conductive film 774, and a liquid crystal layer 776. The conductive film 774 is provided on the second base 705 side and has a function of a counter electrode. The display module 700 in FIG. 25 is capable of displaying an image in such a manner that transmission or non-transmission of light is controlled by change in the alignment state of the liquid crystal layer 776 in accordance with a voltage applied to the conductive film 772 and the conductive film 774.

As the liquid crystal element used for the liquid crystal layer 776, thermotropic liquid crystal, low-molecular liquid crystal, high-molecular liquid crystal, polymer dispersed liquid crystal, ferroelectric liquid crystal, anti-ferroelectric liquid crystal, or the like can be used. Such a liquid crystal material exhibits a cholesteric phase, a smectic phase, a cubic phase, a chiral nematic phase, an isotropic phase, or the like in accordance with conditions.

The conductive film 772 is connected to the conductive film functioning as a source electrode or a drain electrode included in the transistor 750. The conductive film 772 is formed over the planarization insulating layer 770 to function as a pixel electrode, i.e., one electrode of the display element. The conductive film 772 has a function of a reflective electrode. The display module 700 in FIG. 25 is what is called a reflective color liquid crystal display device in which external light is reflected by the conductive film 772 to display an image through the coloring film 736.

A conductive film that transmits visible light or a conductive film that reflects visible light can be used for the conductive film 772. For example, a material including one kind selected from indium (In), zinc (Zn), and tin (Sn) is preferably used for the conductive film that transmits visible light. For example, a material including aluminum or silver may be used for the conductive film that reflects visible light. In this embodiment, the conductive film that reflects visible light is used as the conductive film 772.

In the case where a conductive film that reflects visible light is used as the conductive film 772, the conductive film may have a stacked-layer structure. For example, a 100-nm-thick aluminum film is formed as the bottom layer, and a 30-nm-thick silver alloy film (e.g., an alloy film including silver, palladium, and copper) is formed as the top layer. Such a structure makes it possible to obtain the following effects.

(1) Adhesion between the base film and the conductive film 772 can be improved. (2) The aluminum film and the silver alloy film can be collectively etched depending on a chemical solution. (3) The conductive film 772 can have a favorable cross-sectional shape (e.g., a tapered shape). The reason for (3) is as follows: the etching rate of the aluminum film with the chemical solution is lower than that of the silver alloy film, or etching of the aluminum film that is the bottom layer is developed faster than that of the silver alloy film because when the aluminum film that is the bottom layer is exposed after the etching of the silver alloy film that is the top layer, electrons are extracted from metal that is less noble than the silver alloy film, i.e., aluminum that is metal having a high ionization tendency, and thus etching of the silver alloy film is suppressed.

Note that projections and depressions are provided in part of the planarization insulating layer 770 of the pixel portion 702 in the display module 700 in FIG. 25. The projections and depressions can be formed in such a manner that the planarization insulating layer 770 is formed using an organic resin film or the like, and projections and depressions are formed on the surface of the organic resin film. The conductive film 772 functioning as a reflective electrode is formed along the projections and depressions. Therefore, when external light is incident on the conductive film 772, the light is reflected diffusely at the surface of the conductive film 772, whereby visibility can be improved. As illustrated in FIG. 25, a reflective color liquid crystal display device can display an image without a backlight, which enables a reduction in power consumption.

Note that an example in which the display module 700 illustrated in FIG. 25 is a reflective color liquid crystal display module has been described, but the module type is not limited thereto. For example, the conductive film 772 may be a conductive film that transmits visible light such that a transmissive color liquid crystal display module is obtained. For a transmissive color liquid crystal display module, projections and depressions need not necessarily be provided on the planarization insulating layer 770.

Although not illustrated in FIG. 25, an alignment film may be provided on a side of the conductive film 772 in contact with the liquid crystal layer 776 and on a side of the conductive film 774 in contact with the liquid crystal layer 776. Although not illustrated in FIG. 25, an optical member (an optical substrate) and the like such as a polarizing member, a retardation member, or an anti-reflection member may be provided as appropriate. For example, circular polarization may be employed by using a polarizing substrate and a retardation substrate. For a transmissive display module or a semi-transmissive display module, a backlight, a sidelight, or the like may be used as a light source.

Note that in the case where a horizontal electric field mode is employed for the liquid crystal element, a liquid crystal exhibiting a blue phase for which an alignment film is unnecessary may be used. A blue phase is one of liquid crystal phases, which is generated just before a cholesteric phase changes into an isotropic phase while temperature of cholesteric liquid crystal is increased. Since the blue phase appears only in a narrow temperature range, a liquid crystal composition in which several weight percent or more of a chiral material is mixed is used for the liquid crystal layer in order to improve the temperature range. The liquid crystal composition containing a liquid crystal showing a blue phase and a chiral material has a short response time and optical isotropy, which eliminates the need for an alignment process. Moreover, the liquid crystal material that exhibits a blue phase has a small viewing angle dependence. An alignment film does not need to be provided and rubbing treatment is thus not necessary; accordingly, electrostatic discharge damage caused by the rubbing treatment can be prevented and defects and damage of the liquid crystal display device in the manufacturing process can be reduced.

In the case where a liquid crystal element is used as the display element, a twisted nematic (TN) mode, an in-plane-switching (IPS) mode, a fringe field switching (FFS) mode, an axially symmetric aligned micro-cell (ASM) mode, an optical compensated birefringence (OCB) mode, a ferroelectric liquid crystal (FLC) mode, an antiferroelectric liquid crystal (AFLC) mode, or the like can be used.

Further, a normally black liquid crystal display device such as a transmissive liquid crystal display device utilizing a vertical alignment (VA) mode may also be used. There are some examples of a vertical alignment mode; for example, a multi-domain vertical alignment (MVA) mode, a patterned vertical alignment (PVA) mode, an ASV mode, or the like can be employed.

This embodiment can be combined with any of the other embodiments in this specification as appropriate.

For example, in this specification and the like, when it is explicitly described that X and Y are connected, the case where X and Y are electrically connected, the case where X and Y are functionally connected, and the case where X and Y are directly connected are included therein. Accordingly, another element may be provided between elements having a connection relation illustrated in drawings and texts, without being limited to a predetermined connection relation, for example, the connection relation illustrated in the drawings and the texts.

Here, X and Y each denote an object (e.g., a device, an element, a circuit, a wiring, an electrode, a terminal, a conductive film, a layer, or the like).

Examples of the case where X and Y are directly connected include the case where an element that allows an electrical connection between X and Y (e.g., a switch, a transistor, a capacitor, an inductor, a resistor, a diode, a display element, a light-emitting element, and a load) is not connected between X and Y, and the case where X and Y are connected without the element that allows the electrical connection between X and Y provided therebetween.

For example, in the case where X and Y are electrically connected, one or more elements that enable electrical connection between X and Y (e.g., a switch, a transistor, a capacitor, an inductor, a resistor, a diode, a display element, a light-emitting element, or a load) can be connected between X and Y. A switch is controlled to be on or off. That is, a switch has a function of becoming conducting or not conducting (being turned on or off) to determine whether current flows therethrough or not. Alternatively, the switch has a function of selecting and changing a current path. Note that the case where X and Y are electrically connected includes the case where X and Y are directly connected.

For example, in the case where X and Y are functionally connected, one or more circuits that enable functional connection between X and Y (e.g., a logic circuit such as an inverter, a NAND circuit, or a NOR circuit; a signal converter circuit such as a DA converter circuit, an AD converter circuit, or a gamma correction circuit; a potential level converter circuit such as a power supply circuit (e.g., a step-up circuit or a step-down circuit) or a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, or a buffer circuit; a signal generation circuit; a memory circuit; and/or a control circuit) can be connected between X and Y. Note that for example, in the case where a signal output from X is transmitted to Y, even when another circuit is provided between X and Y, X and Y are functionally connected. Note that the case where X and Y are functionally connected includes the case where X and Y are directly connected and the case where X and Y are electrically connected.

Note that in this specification and the like, an explicit description “X and Y are electrically connected” means that X and Y are electrically connected (i.e., the case where X and Y are connected with another element or another circuit provided therebetween), X and Y are functionally connected (i.e., the case where X and Y are functionally connected with another circuit provided therebetween), and X and Y are directly connected (i.e., the case where X and Y are connected without another element or another circuit provided therebetween). That is, in this specification and the like, the explicit description “X and Y are electrically connected” is the same as the description “X and Y are connected”.

Note that, for example, the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to one part of Z1 and another part of Z1 is directly connected to X while a drain (or a second terminal or the like) of the transistor is directly connected to one part of Z2 and another part of Z2 is directly connected to Y, can be expressed by using any of the following expressions.

The expressions include, for example, “X Y, a source (or a first terminal or the like) of a transistor, and a drain (or a second terminal or the like) of the transistor are electrically connected to each other, and X the source (or the first terminal or the like) of the transistor, the drain (or the second terminal or the like) of the transistor, and Y are electrically connected to each other in this order”, “a source (or a first terminal or the like) of a transistor is electrically connected to X a drain (or a second terminal or the like) of the transistor is electrically connected to Y, and X the source (or the first terminal or the like) of the transistor, the drain (or the second terminal or the like) of the transistor, and Y are electrically connected to each other in this order”, and “X is electrically connected to Y through a source (or a first terminal or the like) and a drain (or a second terminal or the like) of a transistor, and X the source (or the first terminal or the like) of the transistor, the drain (or the second terminal or the like) of the transistor, and Y are provided to be connected in this order”. When the connection order in a circuit configuration is defined by an expression similar to the above examples, a source (or a first terminal or the like) and a drain (or a second terminal or the like) of a transistor can be distinguished from each other to specify the technical scope.

Other examples of the expressions include, “a source (or a first terminal or the like) of a transistor is electrically connected to X through at least a first connection path, the first connection path does not include a second connection path, the second connection path is a path between the source (or the first terminal or the like) of the transistor and a drain (or a second terminal or the like) of the transistor, Z1 is on the first connection path, the drain (or the second terminal or the like) of the transistor is electrically connected to Y through at least a third connection path, the third connection path does not include the second connection path, and Z2 is on the third connection path”. It is also possible to use the expression “a source (or a first terminal or the like) of a transistor is electrically connected to X through at least Z1 on a first connection path, the first connection path does not include a second connection path, the second connection path includes a connection path through the transistor, a drain (or a second terminal or the like) of the transistor is electrically connected to Y through at least Z2 on a third connection path, and the third connection path does not include the second connection path”. Still another example of the expression is “a source (or a first terminal or the like) of a transistor is electrically connected to X through at least Z1 on a first electrical path, the first electrical path does not include a second electrical path, the second electrical path is an electrical path from the source (or the first terminal or the like) of the transistor to a drain (or a second terminal or the like) of the transistor, the drain (or the second terminal or the like) of the transistor is electrically connected to Y through at least Z2 on a third electrical path, the third electrical path does not include a fourth electrical path, and the fourth electrical path is an electrical path from the drain (or the second terminal or the like) of the transistor to the source (or the first terminal or the like) of the transistor”. When the connection path in a circuit configuration is defined by an expression similar to the above examples, a source (or a first terminal or the like) and a drain (or a second terminal or the like) of a transistor can be distinguished from each other to specify the technical scope.

Note that these expressions are examples and there is no limitation on the expressions. Here, X Y, Z1, and Z2 each denote an object (e.g., a device, an element, a circuit, a wiring, an electrode, a terminal, a conductive film, and a layer).

Even when independent components are electrically connected to each other in a circuit diagram, one component has functions of a plurality of components in some cases. For example, when part of a wiring also functions as an electrode, one conductive film functions as the wiring and the electrode. Thus, “electrical connection” in this specification includes in its category such a case where one conductive film has functions of a plurality of components.

This application is based on Japanese Patent Application serial no. 2014-243348 filed with Japan Patent Office on Dec. 1, 2014, the entire contents of which are hereby incorporated by reference.

What is claimed is:

1. A display panel comprising:
a terminal;
a first base being configured to support the terminal;
a second base overlapping with the first base;
a bonding layer between the first base and the second base;
a display element between the first base and the second base, the display element being electrically connected to the terminal; and
an insulating layer being in contact with the first base, the second base, and the bonding layer,
wherein the insulating layer comprises a first opening overlapping with the display element.

2. The display panel according to claim 1, further comprising a resin layer,
wherein part of the insulating layer is positioned between the resin layer and the bonding layer.

3. The display panel according to claim 1, wherein each of the first base and the second base has flexibility.

4. The display panel according to claim 1, wherein the bonding layer is positioned outside of the display element.

5. The display panel according to claim 1, wherein the display element comprises a light-emitting organic compound.

6. The display panel according to claim 1, wherein the display element comprises a liquid crystal.

7. The display panel according to claim 1, wherein the insulating layer is in contact with side surfaces of the first base, the second base, and the bonding layer.

8. The display panel according to claim 1, wherein the insulating layer is in contact with outer surfaces of the first base, the second base, and the bonding layer.

9. The display panel according to claim 1, wherein the insulating layer further comprises a second opening overlapping with the terminal.

10. The display panel according to claim 1, wherein the first opening is positioned on each of an outer surface of the first base and an outer surface of the second base.

11. A display module comprising:
the display panel according to claim 1; and
a flexible printed circuit being electrically connected to the terminal.

12. A method for manufacturing a display panel comprising:
the display panel comprising:
a terminal;
a first base being configured to support the terminal;
a second base overlapping with the first base;
a bonding layer between the first base and the second base;
a display element between the first base and the second base, the display element being electrically connected to the terminal; and
an insulating layer being in contact with the first base, the second base, and the bonding layer,
the method comprising the steps of:
preparing a processed member comprising the terminal, the first base, the second base, the bonding layer, and the display element;
forming a mask overlapping with the display element;
forming the insulating layer by an atomic layer deposition method; and
removing part of the insulating layer and the mask to form an opening in the insulating layer.
